(19) United States
(12) Patent Application Publication
(10) Pub. No.: US 2001/0055733 A1
(43) Pub. Date: Dec. 27, 2001

(54) Exposure method and exposure apparatus

(75) Inventors: Nobuyuki Irie, Kawasaki-shi (JP); Nobutaka Magome, Oosato-gun (JP)

Correspondence Address: OLIFF & BERRIDGE, PLC, P.O. BOX 19928, ALEXANDRIA, VA, 22320, US

(73) Assignee: Nikon Corporation

(21) Appl. No.: 09/827,946

(22) Filed: Apr. 9, 2001

(30) Foreign Application Priority Data
Apr. 11, 2000 (JP) 2000-109144
Mar. 14, 2001 (JP) 2001-071572

(51) Int. Cl. G03F 9/00; G03F 7/20

(52) U.S. Cl. 430/396; 430/311; 430/5; 430/397; 355/18

(57) ABSTRACT

An exposure method which irradiates a slit-shaped illumination light IL on a reticle Ri and a substrate while moving them synchronously so as to sequentially transfer images of patterns formed on the reticle Ri to the substrate 4, wherein a density filter Fj having an attenuating part for gradually reducing the distribution of illuminance of the illumination light IL is moved in synchronization with the movement of the reticle Ri.

### BACKGROUND OF THE INVENTION

1. Field of the invention

The present invention relates to an exposure method and exposure apparatus used when producing a semiconductor integrated circuit, a liquid crystal display device, a thin film magnetic head, or another microdevice or a photomask by photolithography.

2. Description of the Related Art

In photolithography, one step in the production of a microdevice, use is made of an exposure apparatus for projection exposure of images of patterns of a photomask or reticle on to a substrate for exposure (semiconductor water or glass plate coated with a photoresist, light-transparent substrate called a “blank”, etc.) In recent years, to deal with the increasingly large size of the exposure area accompanying the increased size of substrates, a block exposure type stitch exposure apparatus which partitions the exposure area of the substrate into a plurality of unit areas (hereinafter sometimes referred to as “shots” or “shot areas”) and successively projects and exposes images of corresponding patterns on the shots has been developed.

In such an exposure apparatus, there was sometimes misalignment in stitched portions of shots due to aberration of the projection optical system, positioning error of the mask or substrate, etc. Therefore, part of the image of the pattern for one shot was superposed over part of the image of the pattern for another shot adjoining it for the exposure. At overlay parts of images of patterns (also called “stitched parts,), the exposure becomes greater than portions other than overlay parts, so for example the line width (width of lines or spaces) at overlay parts of patterns formed on the substrate becomes thinner or thicker in accordance with characteristics of the photoresist.

Therefore, the distribution of exposure at peripheral parts (portions forming overlay parts) of the shots is set to a slant so as to become smaller the further toward the outside and the overall exposure of overlay parts is made equal to the exposure of portions other than overlay parts by two exposures so as to realize seamless stitching with little change in line width at these overlay parts.

As a technique for realizing slanted distribution of exposure at peripheral parts of shots, it is known to form light-attenuating parts limiting in a slanting fashion the amount of light transmittance at portions of the reticle itself corresponding to overlay parts. Due to the formation of the light-attenuating parts in the reticle itself, however, the steps and cost of the manufacturing process of the reticle increase and the cost of manufacturing the microdevice etc. increase.

Therefore, an exposure apparatus is being developed which is provided with a density filter formed with light-attenuating parts similar to the above on a glass plate at positions substantially conjugate with the pattern formation surface of the reticle or which is provided with a blind mechanism having light-blocking plates (blinds) able to advance into or retract from the optical path at positions substantially conjugate with the pattern formation surface of the reticle and realizes a slanted distribution of exposure by making the light-blocking plates advance or retract during the exposure of the substrate.

The above exposure apparatus, however, is a block exposure type exposure apparatus which performs exposure with the reticle and the substrate in a stationary state. Recently, however, a scan type (sequential exposure type) exposure apparatus has been developed from the viewpoints of the reduction of the distortion of the projection optical system, the overall focus error (including curvature of the imaging plane and tilt of the imaging plane), line width error, and other various types of error, the improvement of the resolution, the ease of correction of trapezoidal distortion and error of flatness etc., and the like. A scan type exposure apparatus makes the reticle and substrate move synchronously with respect to illumination light shaped into a slit in cross-section so as to sequentially project and exposure corresponding images of patterns on the shots.

When performing stitch exposure by such a scan type exposure apparatus as a technique for adjusting the exposure at the peripheral parts of the shots for realizing seamless stitching as explained above, it is known to shape the slit-shaped illumination light to a trapezoidal or hexagonal cross-section, that is, to make the shape of the end of the illumination light in the direction perpendicular to the scan direction narrower the further to the front end, so as to give an incline to the cumulative exposure of the peripheral parts.

With this technique of shaping the illumination light, however, while it is possible to seamlessly stitch the shots in the direction perpendicular to the scan direction, it is not possible to seamlessly stitch in the direction along the scan direction. That is, there was the problem that it was only possible to stitch in a one-dimensional direction and was not possible to stitch in a two-dimensional direction.

Further, recently, excimer laser light and other pulse light has sometimes been used as the illumination light, but there is relatively large variation in the exposure in pulse units of such pulse light. Therefore, in a wide part of the slit light, since a large number of pulses are fired, the effect becomes averaged out and sufficient uniformity can be realized, but at the narrow part of the end of the slit light, the number of pulses is not sufficient for averaging and therefore the exposure at the stitched parts does not become uniform and remains uneven. This results in the problem of poor accuracy of the patterns at the stitched parts in some cases.

### SUMMARY OF THE INVENTION

An object of the present invention is to provide an exposure method and exposure apparatus able to realize seamless stitch exposure not only in a direction perpendicular to the scan direction, but also a direction along the scan direction. Another object is to realize a good uniformity of the line width or pitch of the patterns at the stitching parts and a high accuracy of patterns even when using pulse light as illumination light.

Another object of the present invention is to provide a step-and-stitch type exposure method and apparatus enabling realization of uniformity of the cumulative amount of light (exposure dome) at exposure areas on the substrate, in particular, the overlay parts of two or more shot areas with overlapping peripheral parts, and in turn the line width of the patterns (transferred images).

According to a first aspect of the present invention, there is provided an exposure method which irradiates a slit-shaped energy bean on a mask and a sensitive object while moving them synchronously so as to sequentially transfer images of patterns formed on the mask to the sensitive object, including a step of moving a density filter having a attenuating part for gradually reducing the amount of energy of the energy beam in sychronization with the movement of the mask.

According to a second aspect of the present invention, there is provided an exposure method which relatively moves a mask and a sensitive object with respect to an energy beam and scans and exposes the sensitive object by the energy beam through the mask, including a step of gradually reducing an amount of energy in a part of an area irradiated by the energy beam on the sensitive object in a first direction in which the sensitive object is moved, while relatively moving a slope part where the amount of energy is gradually reduced in the first direction in said irradiated area during the scan exposure.

According to a third aspect of the present invention, there is provided an exposure apparatus which irradiates a slit-shaped energy beam on a mask and a sensitive object while moving them synchronously so as to sequentially transfer images of patterns formed on the mask to the sensitive object, comprising a density filter which adjusts the distribution of energy of the energy beam and a filter stage which moves the density filter in synchronization with the mask.

According to a fourth aspect of the present invention, there is provided an exposure apparatus comprising a mask stage which moves a mask, a substrate stage which moves a substrate, an illumination optical system which irradiates a slit-shaped energy beam, a filter stage which moves a density filter having an attenuating part for gradually reducing an amount of energy of said energy beam, and a controller which controls said mask stage, said substrate stage, and said filter stage so that said substrate and said density filter move synchronously with respect to said energy been.

According to a fourth aspect of the present invention, there is provided an exposure apparatus which relatively moves a mask and a sensitive object with respect to an energy beam and scans and exposes the sensitive object by the energy beam through the mask, comprising a density filter which gradually reduces an amount of energy in a part of an area irradiated by the energy beam on the sensitive object in a first direction in which the sensitive object is moved and an adjuster which shifts a slope part where the amount of energy is gradually reduced in the first direction in said irradiated area during the scan exposure.

According to a fourth aspect of the present invention, there is provided an exposure apparatus in which a mask and a sensitive object are moved relative to an energy beam and the sensitive object is scanned exposed by the energy beam through the mask, comprising a first optical unit which defines the width of an area irradiated by the energy beam on the sensitive object in a first direction in which the sensitive object is moved during the scan exposure, and a second optical unit which gradually reduces an amount of energy in a part of the irradiated area in the first direction, while shifting a slope part which the amount of energy is gradually reduced in the first direction within the irradiated area during the scan exposure.

According to the present invention, since the density filter (or slope part) is moved in synchronization with the movement of the mask, it is possible to expose the peripheral parts of shots giving a distribution of the cumulative amount of energy in accordance with the characteristics of the attenuating part of the density filter (or distribution of amount of energy of slope part). Therefore, it becomes possible to achieve seamless stitch exposure in both of a direction perpendicular to the scan direction and a direction along the scan direction.

Further, even when using excimer laser light or other pulse light as the energy beam, the averaging effect of the large number of pulses is sufficiently manifested, so there is little variation in the cumulative amount of energy at the stitched parts of the shots, the uniformity of line width and pitch of the patterns at the stitched parts becomes good, and patterns can be formed with high accuracy.

### BRIEF DESCRIPTION OF THE DRAWINGS

These and other objects and features of the present invention will become clearer from the following description of the preferred embodiments given with reference to the attached drawings, in which:

FIG. 1 is a view of the general configuration of an exposure apparatus according to an embodiment of the present invention;

FIG. 2A is a plan view of the configuration of a density filter according to an embodiment of the present invention;

FIG. 23 is a view of an example of marks formed on a density filter of FIG. 2A;

FIGS. 3A to FIG. 3I are views of configurations of nine types of density filters able to be used for embodiments of the present invention;

FIG. 4 is a perspective view of the case when projecting a reduced image of a parent pattern of a master reticle on a substrate according to an embodiment of the present invention;

FIG. 5 is a view for explaining measurement of a slit mark according to an embodiment of the present invention;

FIG. 6 is a view for explaining a process of production when producing a reticle (working reticle) using a master reticle according to an embodiment of the present invention;

FIG. 7 is a view of an alignment mechanism of a reticle according to an embodiment of the present invention;

FIG. 8 is a view, seen from the side, of the arrangement of key parts of the embodiment of the present invention in the direction along the optical axis;

FIG. 9 is a view, seen from the light source side, of the arrangement of key parts of the embodiment of the present invention in the direction along the optical axis;

FIG. 10A is a view of the arrangement of parts at the time of measurement of a mark of a density filter according to an embodiment of the present invention;

FIG. 10B is a view of another arrangement of parts at the time of measurement of a mark of a density filter according to an embodiment of the present invention;

FIG. 11A is a view of the state of scanning of a projected image of a mark for measurement of a slit mark according to an embodiment of the present invention;

FIG. 11B is a view of the output of a photoelectric sensor at the time of measurement of a slit mark according to an embodiment of the present invention;

FIG. 12A is a view, seen from the side, of the arrangement of parts along the optical axis before the start of scan exposure according to an embodiment of the present invention;

FIG. 12B is a view, seen from the light source side, of the arrangement of parts along the optical axis before the start of scan exposure according to an embodiment of the present invention;

FIG. 13A is a view, seen from the side, of the arrangement of parts along the optical axis directly after the start of scan exposure according to an embodiment of the present invention;

FIG. 13B is a view, seen from the light source side, of the arrangement of parts along the optical axis directly after the start of scan exposure according to an embodiment of the present invention;

FIG. 14A is a view, seen from the side, of the arrangement of parts along the optical axis during scan exposure according to an embodiment of the present invention;

FIG. 14B is a view, seen from the light source side, of the arrangement of parts along the optical axis during scan exposure according to an embodiment of the present invention;

FIG. 15A is a view, seen from the side, of the arrangement of parts along the optical axis immediately before the end of scan exposure according to an embodiment of the present invention;

FIG. 15B is a view, seen from the light source side, of the arrangement of parts along the optical axis immediately before the end of scan exposure according to an embodiment of the present invention;

FIG. 16A is a view, seen from the side, of the arrangement of parts along the optical axis immediately after the end of scan exposure according to an embodiment of the present invention; and

FIG. 16B is a view, seen from the light source side, of the arrangement of parts along the optical axis immediately after the end of scan exposure according to an embodiment of the present invention.

### DESCRIPTION OF THE PREFERRED EMBODIMENTS

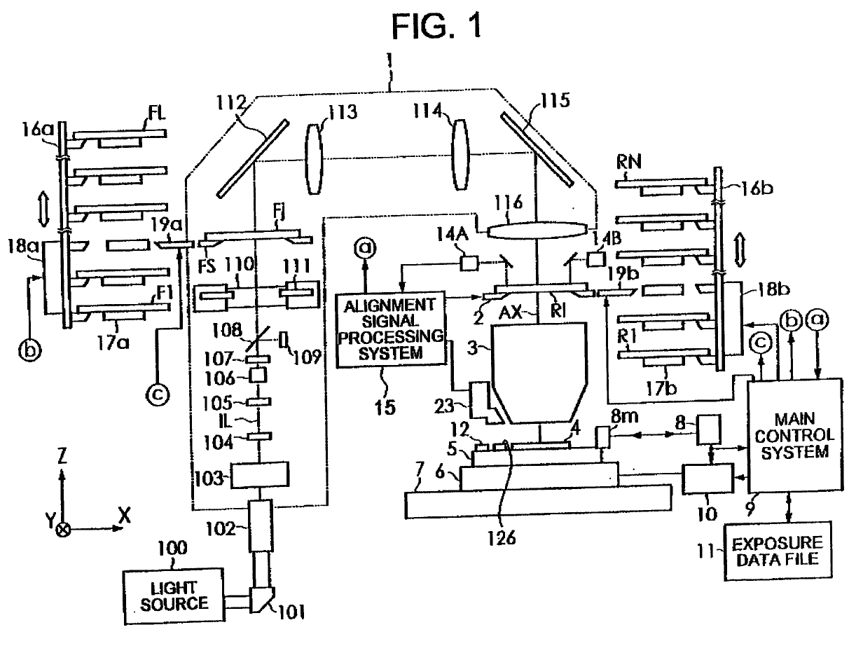

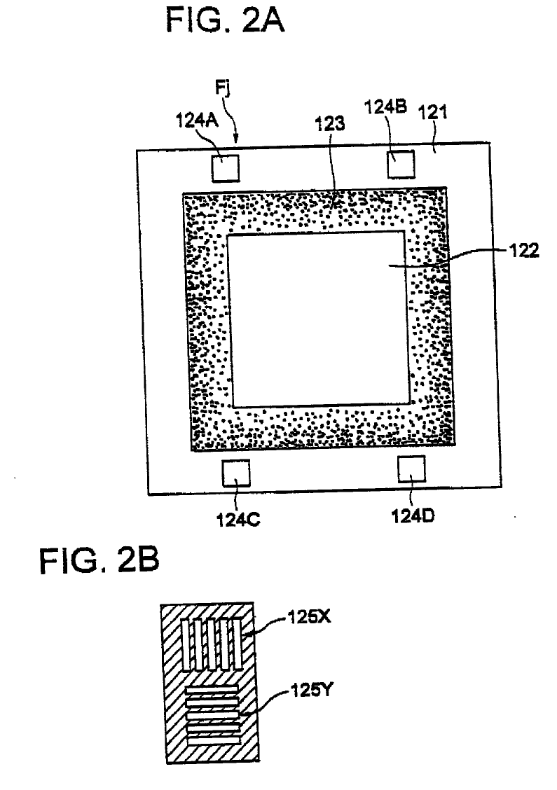

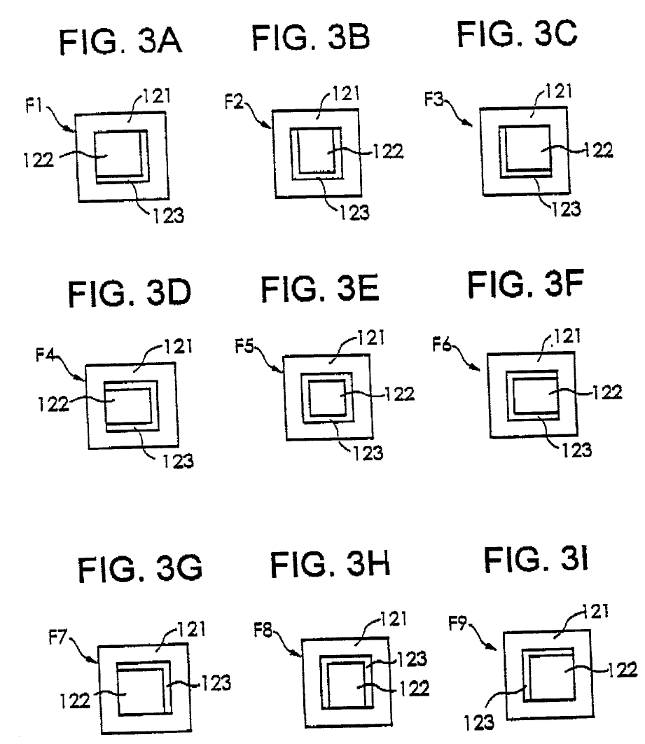

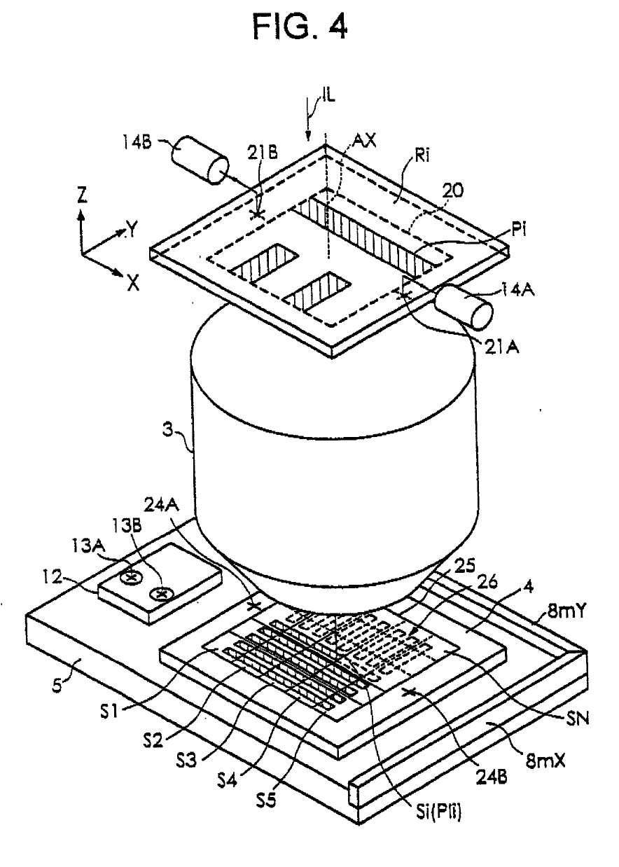

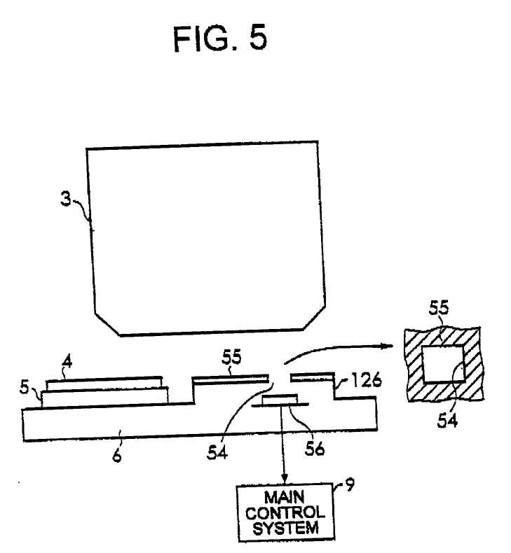

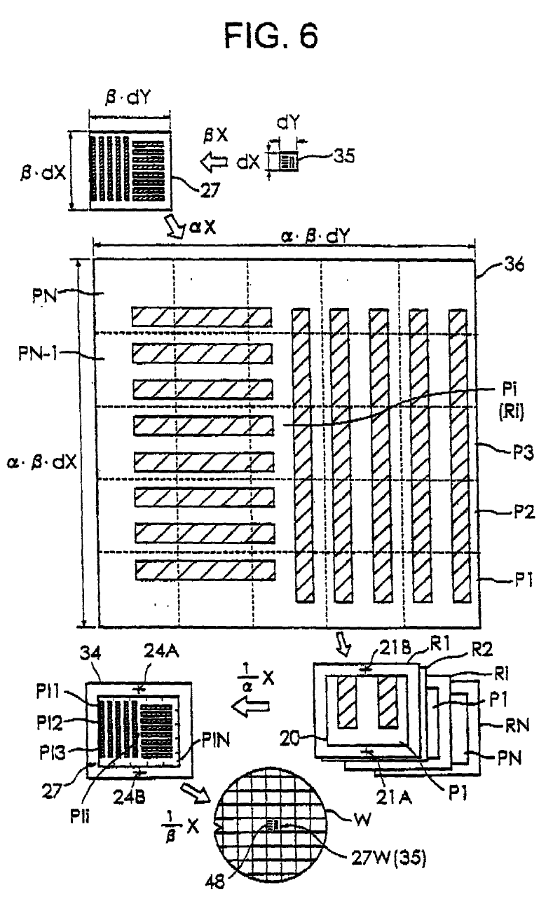

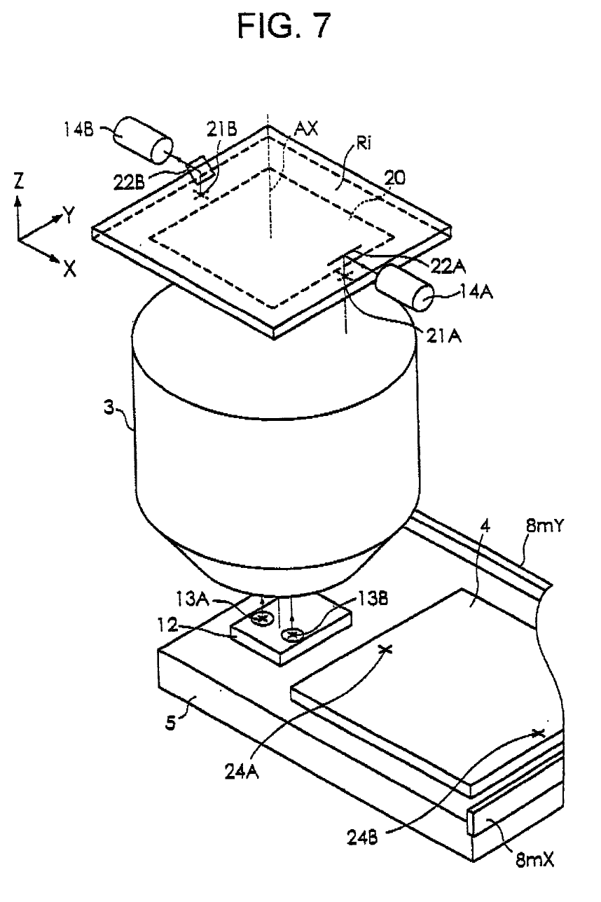

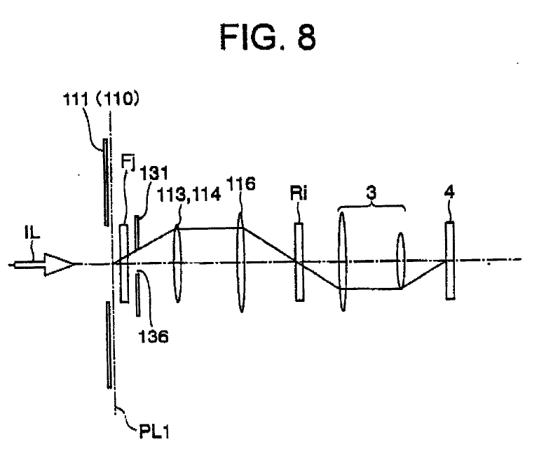

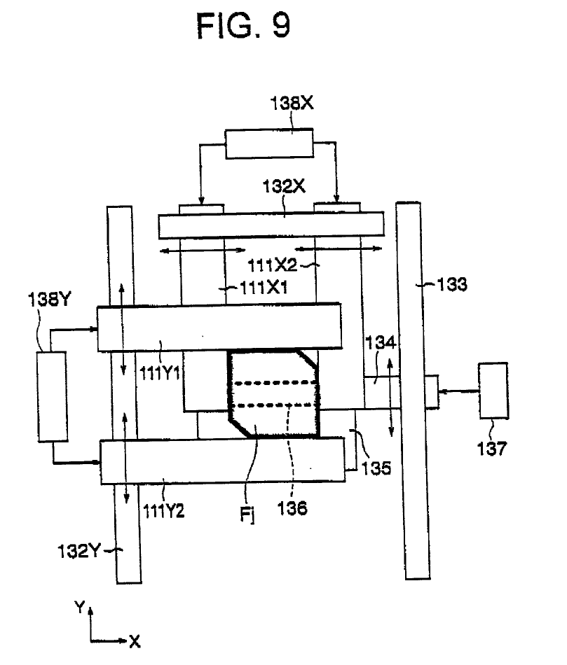

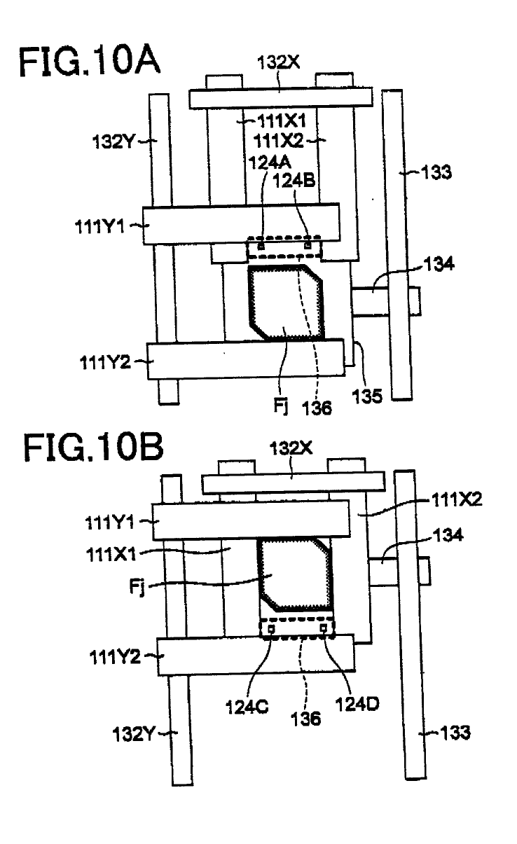

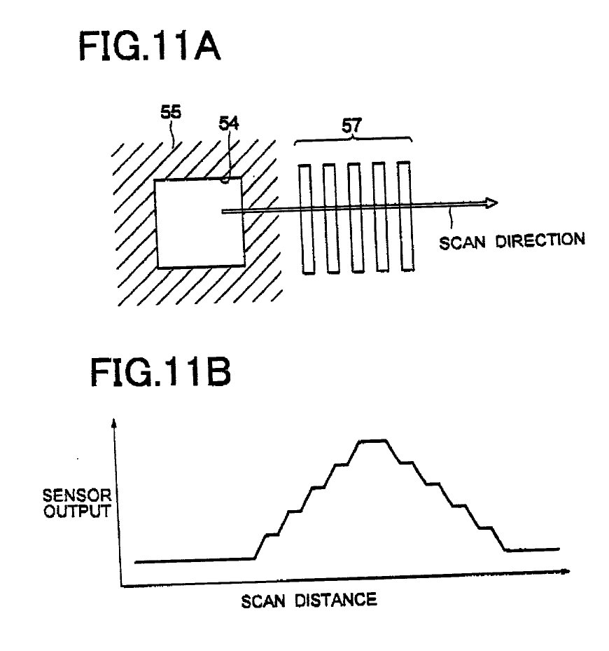

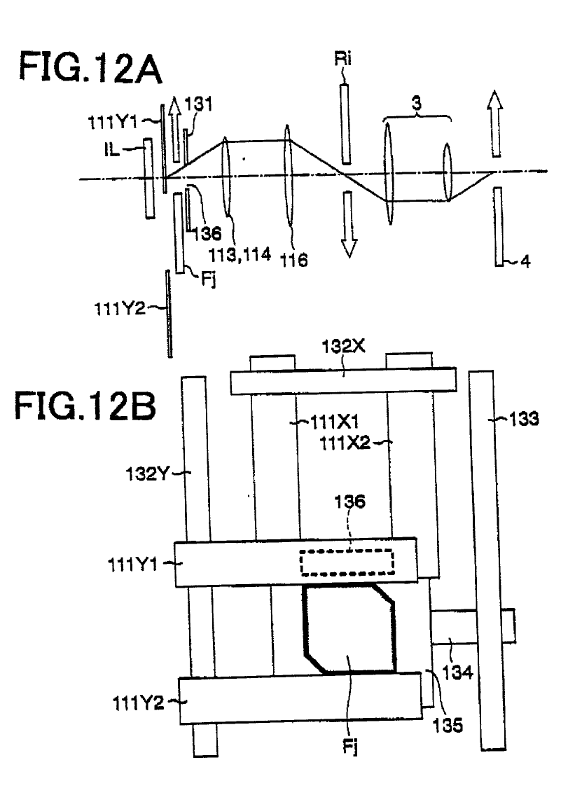

Below, an explanation will be given of an embodiment of the present invention with reference to the drawings. FIG. 1 is a view of the general configuration of an exposure apparatus according to an embodiment of the present invention. The exposure apparatus is a step-and-scan type stitch projection exposure apparatus. Further, in the following explanation, the XYZ orthogonal coordinate system shown in FIG. 1 is set and the positional relationships of the members explained while referring to the XYZ orthogonal coordinate system. The XYZ orthogonal coordinate system is set so that the X-axis and the Z-axis become parallel to the paper surface and so that the Y-axis becomes the direction perpendicular to the paper surface. Further, the XYZ coordinate system in the figure is set so that the XY plane becomes a plane parallel to the horizontal surface and the Z-axis becomes the vertical direction. The direction along the Y-axis is the scan direction.

In FIG. 1, the ultraviolet pulse light IL of the light from a light source 100 (here, an ArF excimer laser) (hereinafter referred to as the “exposure light IL”) passes through a beam matching unit (BMU) 101 including movable mirrors etc. for matching of the position of the optical path with the illumination optical system 1 and enters a variable light-attenuator 103 serving as a light-attenuator through a pipe 102.

A main control system 9 controls the amount of exposure to the resist on the substrate 4 by communicating with the light source 100 to start and stop emission of light and control the output as determined by the oscillation wavelength and the pulse energy and to adjust the light-attenuation rate of the variable light-attenuator 103 with respect to the exposure light IL in stages or continuously.

The exposure light IL passing through the variable light-attenuator 103 passes through a beam shaping optical system comprised of lens systems 104 and 105 arranged along a predetermined optical axis and enters an optical integrator (for example internal-reflection type integrator (rod integrator or the like), fly-eye lens (shown in FIG. 1) or diffraction optical element etc.) Further, two fly-eye lenses 106 may be arranged in series to enhance the uniformity of illumination distribution.

An aperture stop system 107 is arranged at the emission surface of the fly-eye lens 106. The aperture stop system 107 includes a circular aperture stop for normal illumination, an aperture stop for modified illumination comprised of a plurality of small offset apertures, an aperture stop for annular illumination, etc. arranged in a switchable manner. The illumination light IL emitted from the fly-eye lens 106 and passing through a predetermined aperture stop of the aperture stop system 107 enters a beam splitter 108 having a high transmittance and a low reflectance. The light reflected at the beam splitter 108 enters an integrator sensor 109 comprised of a photoelectric detector. The detection signal of the integrator sensor 109 is supplied through a not illustrated signal line to the main control system 9.

The transmittance and reflectance of the beam splitter 108 are measured to a high accuracy in advance and stored in a memory in the main control system 9. The main control systems 9 is designed to he able to monitor the exposure light IL entering the projection optical system 3 indirectly by the detection signal of the integrator sensor 109 and in turn the mount of the illumination light on the substrate 4.

The exposure light IL passing through the beam splitter 108, as shown in FIG. 8, enters a reticle blind mechanism 110, a density filter Fj held on a filter stage FS (not show in FIG. 8), and a fixed slit plate 131 (not shown in FIG. 1) in that order.

The reticle blind mechanism 110 is comprised of four movable blinds 111 (111X1, 111X2, 111Y1, and 111Y2) and their drive mechanisms. As shown in FIG. 9, the blinds 111X1 and 111X2 are supported to be able to move in the X-direction along an I-direction blind guide 132X. These blinds 111X1 and 111X2 are designed to be driven independently by drive mechanisms 138X (linear motor or the like) and can be positioned at any position in the X-direction. Further, the blinds 111X1 and 111X2 can also be finely adjusted in their postures.

The blinds 111Y1 and 111Y2 are supported to be able to move in the Y-direction along a Y-direction blind guide 132Y. These blinds 111Y1 and 111Y2 are designed to be driven independently by drive mechanisms 138Y (linear motor or the like) and can be positioned at any position in the Y-direction. Further, the blinds 111Y1 and 111Y2 can also be finely adjusted in their postures. Further, the blinds 111Y1 and 111Y2 are designed to be able to move in the Y-direction in synchronization with the later explained scan operation of the reticle Ri, density filter Fj, and substrate 4 in the state maintaining their relative positional relationships.

The blinds 111Y1 and 111Y2 are driven by completely independent drive mechanisms 138Y and may be moved synchronously in addition to being adjusted in posture and positioned. However, independent fine-movement drive mechanisms (for example,, voice coil motor or EI core) may be provided for the blinds 111Y1 and 111Y2, respectively, for the posture adjustment and positioning of latter, while a single coarse-movement drive mechanism (for example linear motor) may be provided, as the drive mechanisms 138Y, for the synchronous movement of the blinds 111Y1 and 111Y2 with the reticle Ri, density filter Fj and substrate 4.

The illumination light IL passing through the blinds 111 of the reticle blind mechanism 110 eaters the density filter Fj held on the filter stage FS. The filter stage FS, as shown in FIG. 9, is comprised by a filter guide 133 extending along the Y-direction, a filter holder 135 supported movably with respect to said filter guide 133 through a support member 134, and a drive mechanism (for example linear motor) 137. The density filter Fj is supported to be able to be attached to the filter holder 135 and can be moved in synchronization with the later explained scan operation of the reticle Ri and the substrate 4 by the filter stage FS. Further, the filter holder 135 has an adjustment mechanism enabling the held density filter Fj to be finely moved in the XY plane in the rotational direction and the translational direction, to be finely moved in the Z-direction, and to be tilted two-dimensionally with respect to the XY plane.

The position of the filter stage FS (density filter Fj) in the Y-direction is measured by a not shown laser interferometer or linear encoder etc. The operation of the filter stage FS, including the synchronous movement, is controlled by the measured value and control information from the main control system 9.

Near the downstream side of the density filter Fj, as shown in FIG, 8, is provided a fired slit plate (fixed blind) 132 having a thin rectangular slit (aperture) 136 extending in the X-direction. The illumination light IL passing through the density filter Fj is shaped to thin, rectangular-section light extending in the X-direction by the slit 136 of the fixed slit plate 131. In this embodiment, the slit 136 in the fixed slit plate 131 has an X-directional opening thereof set equal or larger than the width of the density filter Fj. Therefore, an area on the reticle Ri illuminated with the illumination light IL from the illumination optical system 1, and an area conjugate with the illuminated area with respect to a projection optical system 3 which will further be described later and on which a pattern image of the reticle Ri is projected (namely, an exposure area on the substrate 4, illuminated with the illumination light IL from the projection optical system 3), will have a width in the scan direction (Y-direction) along which the reticle Ri and substrate 4 are moved during scan exposure, defined by the fixed slit plate 131 (and the blinds 111Y1 and 111Y2), and also a width in the non-scanning direction (X-direction) perpendicular to the scan direction, defined substantially by the density filter Fj (and the blinds 111X1 and 111X2).

As shown in FIG. 8, the blinds 111 of the reticle blind mechanism 110, the surface of the density filter Fj on which the dot pattern (explained later) comprising the light-attenuating part 123 is formed, and the fixed slit plate 131 are arranged near the plane PL1 conjugate with the pattern formation surface of the later explained reticle Ri. Note that the blinds 111Y1 and 111Y2 limiting the width of at least a part of the blind 111 of the reticle blind mechanism 110, for example, the width of the illuminated area (and the projection area) in the aforementioned scan direction (X-direction), may be provided in their conjugate plane PL1. Here, the density filter Fj and the fixed alit plate 131 are deliberately set to be slightly defocused from the reticle conjugate plane PL1.

This defocusing is caused for the following reason. That is, for the density filter Fj, this is so that the dot pattern comprising the light-attenuating part 123 is not resolved on the pattern formation surface of the reticle Ri (conjugate with surface of substrate 4 being exposed), in other words, so that the dot pattern acting the substrate 4 is not transferred. Further, for the fixed slit plate 131, since the illumination light IL is pulse light as explained above and there is variation in the amount of light between pulses, this is so as to reduce the deterioration in the control accuracy (uniformity) of the exposure of the substrate 4 due to this variation. Namely, with the fixed slit plate 131 displaced from the above-mentioned conjugate plane PL1 in the illumination optical system 1, the intensity distribution of the illumination light IL in the scan direction (Y-direction) on the reticle R1 (substrate 4) will have slope parts at either end thereof. Thus, as each point on the substrate 4 crosses the slope parts during scan exposure, it will be irradiated to a plurality of pulses of the light and it is possible to prevent the accuracy of control of the amount of exposure on the substrate 4, for example, the uniformity of exposure distribution, from being degraded.

Here, a detailed explanation will be given of the configuration of the density filter Fj etc. The density filter Fj is basically configured as shown in FIG. 2A. The density filter is comprised of a light-transmitting substrate such as silica glass on which are for a light-blocking part 121 on which chrome or another light-blocking material in deposited, a light-transmitting part 122 on which no light-blocking material is deposited, and a light-attenuating part (attenuating part) 123 on which the light-blocking material is deposited while changing the probability of presence. The light-attenuating part 123 has the light-blocking material deposited on it in dots. The size of the dots becomes less than the resolution limit of the optical system (optical elements 112 to 116) disposed between the light-attenuating part 123 and reticle Ri in the state where the density filter Fj is placed at the position shown in FIG. 1 and FIG.

The light-attenuating characteristic of the light-attenuating part 123 (distribution of light-attenuation rate) is set as follows in the present embodiment. Here, in FIG. 2A, the areas where two sides of the four sides making up the rectangular light-attenuating part 123 intersect (the corners) are referred as to the bottom left corner, top left corner, bottom right corner, and top right corner, while the areas of the sides other than the corners are referred to as the left side, right side, top side, and bottom side.

The light-attenuating characteristics of the sides are set so that the light-attenuation rate becomes higher by a linear gradient from the inside of the sides (light-transmitting part 122 side) to the outside, that is, so that the transmittance becomes lower. In other words, they are set so that by exposing the areas where only two adjoining shots on the substrate are overlaid (portions where shots adjoining in the vertical or horizontal direction are overlaid, but shots adjoining diagonally are not overlaid) two times through the left side and right side or top side and bottom side of the light-attenuating part 123, the exposure becomes substantially equal to that of a portion exposed once through the light-transmitting part 122. The light-attenuating characteristics of the sides do not however have to be set to change by a linear gradient. For example, they may be set so that the light-attenuation rate becomes higher along a curve the more from the inside to the outside. That is, the left side and right side or the top side and bottom side may be set to characteristics which complement each other so as to become equal to the exposure of the light-transmitting part 122 by two exposures.

The light-attenuating characteristics of the corners are set based on characteristics of the product of a first characteristic comprised of the light-attenuating characteristic of one of two sides comprising a corner and a second characteristic comprised of the characteristic of the other. In other words, they are set so that by exposing an area on the substrate 4 where four shots overlap (portion where shots adjoining vertically and horizontally all overlap) four times through the bottom left corner, top left corner, bottom right corner, and top right corner of the light-attenuating part 123, the exposure becomes substantially equal to that of the portion exposed once through the light-transmitting part 122.

The light-attenuating characteristics of the corners, however, do not have to be set in the above way. It is sufficient to set the characteristics of the bottom left corner, top left corner, bottom right corner, and top right corner so as to be complementary so as to become equal to exposure of the light-transmitting part 122 by four exposures. Further, it is not necessarily required that the corners be set to symmetrical characteristics. For example, the following is possible. That is, the triangular portion of the bottom left half of the bottom left corner of the light-attenuating part 123 may be set to a 100% light-attenuation rate and the triangular portion of the top right half of the bottom left corner set to a light-attenuation rate which becomes higher by a linear gradient the further outside in the bottom left 45 degree direction. In the same way, the triangular portion of the top right half of the top right corner may be set to a 100% light-attenuation rate and the triangular portion of the bottom left half of the top right corner set to a light-attenuation rate which becomes higher by a linear gradient the further outside in the top right 45 degree direction. The light-attenuating characteristics of the top left corner and the bottom right corner are set based on the characteristics of the addition of a first characteristic comprising the light-attenuating characteristics of one of the two sides comprising each of the top left corner and the bottom right corner and a second characteristic comprising the characteristics of the other. Due to this, the exposure becomes equal to the exposure of the light-transmitting part 122 by four exposures (the light-attenuation rates of the triangular portion of the bottom left half of the bottom left corner and of the triangular portion of the top right half of the top right corner are 100%, so strictly speaking three exposures).

The dots are preferably arranged not by arrangement of dots by the same pitch P at the same transmittance parts in the light-attenuating part 123, but by arrangement by addition to P of a random number R having a Gaussian distribution generated for each dot, that is, a P+R system. The reason is that diffracted light is produced by the arrangement of dots. In some cases, the numerical aperture (NA) of the illumination system is exceeded and light does not reach the photosensitive substrate and therefore the error from the design transmittance becomes large.

Further, the sizes of the dots are preferably all the same. The reason is that if several sizes of dots are used, when error occurs from the design transmittance due to the afore-mentioned diffraction, the error becomes complicated, that is, correction of the transmittance becomes complicated.

The light-attenuating part 123 of the density filter Fj is preferably produced by a high speed electron beam lithography system so as to reduce the error in the dot shape. Further, the shape of the dots is preferably a rectangular shape (square shape) for which process errors in shape can be easily measured. This has the advantage of easy correction of the transmittance in the case of any measurable shape error.

The light-blocking part 121, the light-transmitting part 122, and the light-attenuating part 123 of the density filter Fj are formed corrected in advance to give suitable shapes on the pattern formation surface in accordance with the distance (dimension) in the direction along the optical axis between the plane conjugate with the pattern formation surface of the master reticle Ri and the density filter Fj in the state held on the filter Stage FS.

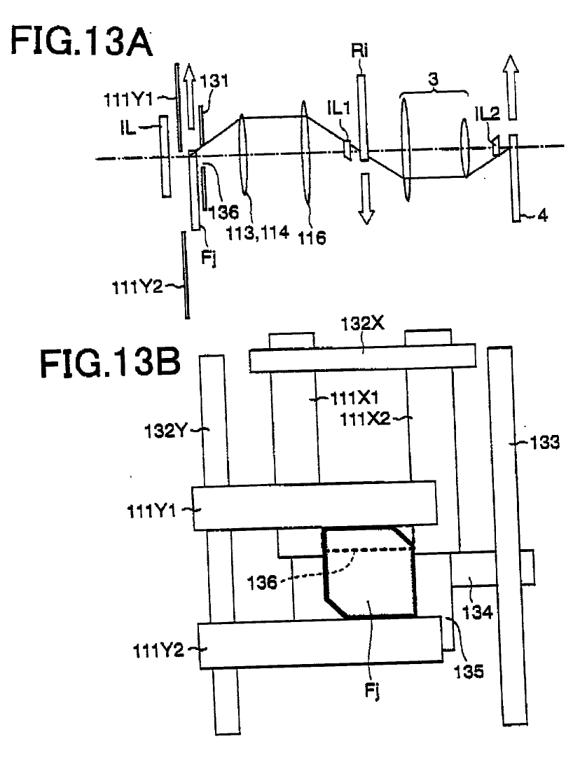

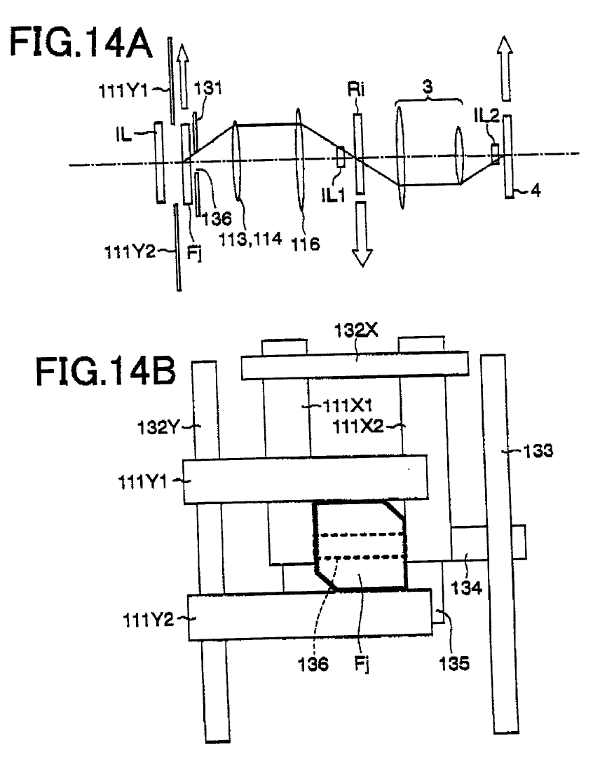

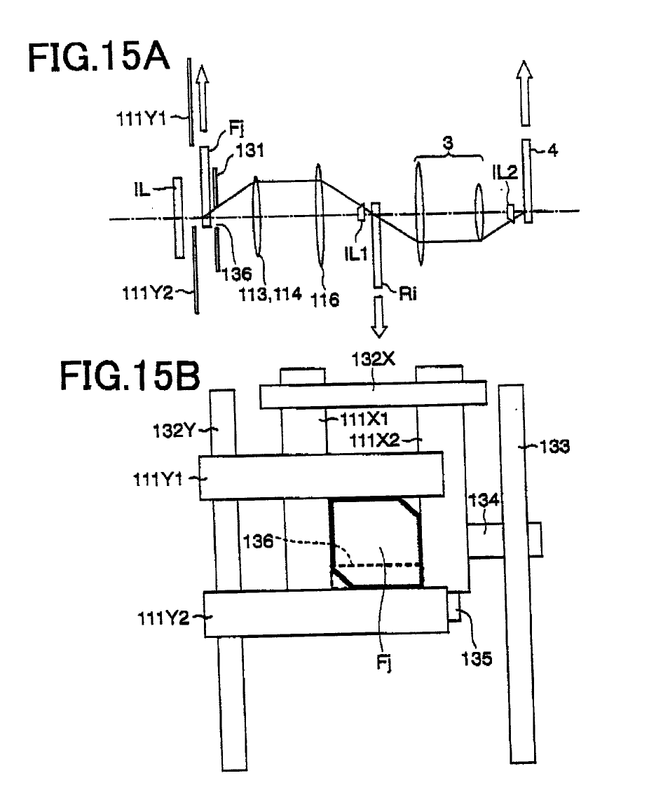

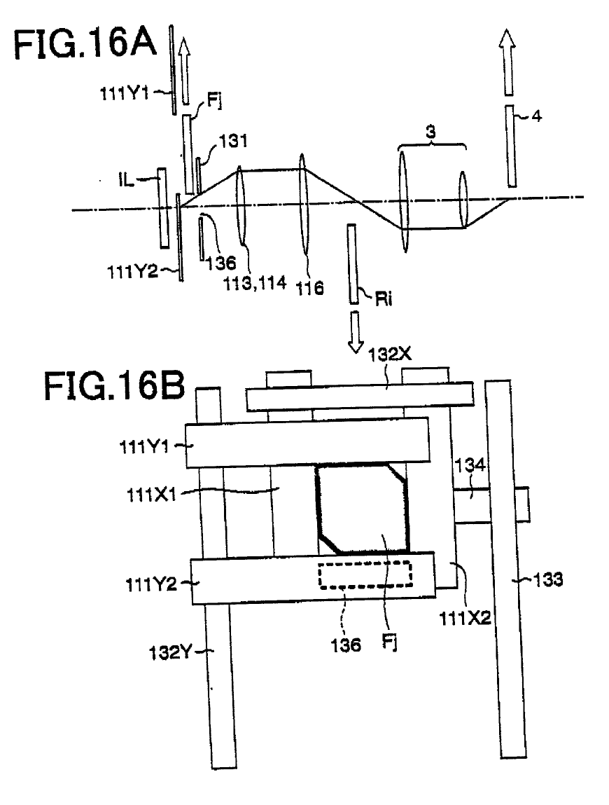

The light-blocking part 121 of the density filter Fj is formed with a plurality of marks 124A, 124B, 124C, and 124D. These marks 124A to 124D can be formed by removing parts of the light-blocking part 121 of the density filter Fj to form rectangular or other shaped apertures (light-transmitting parts). Here, as shown in FIG. 23, a slit mark comprised of a plurality of slit-shaped apertures is employed. This slit mark is comprised of a combination of a mark element 125X comprised of slits formed along the Y-direction aligned in the X-direction and a mark element 125Y comprised of slits formed along the X-direction aligned in the Y-direction for measurement of the positions in the X-direction and Y-direction.

The position in the X- and Y-directions, the mount of rotation in the XY plane, and the projection magnification of the density filter Fj are adjusted by fine movement of the density filter Fj and changing the optical characteristic of the optical system (optical elements 113 and 114, etc.) provided between the density filter Fj and reticle Ri based on positional information acquired through detection of images of the marks 124A, 124B, 124C and 124D on a predetermined surface on which for example the reticle Ri or substrate 4 is disposed (object surface or image surface of the projection optical system 3). Further, the position of the density filter Fj in the Z-direction (amount of defocus) and the amount of tilt in the Z-direction (angle of tilt with respect to XY plane) are adjusted, for example, by moving the density filter Fj based on the position in the Z-direction (best focus position) acquired through detection of images of the marks 124A, 124B, 124C and 124D at a plurality of positions in the Z-direction and where the signal intensity or contrast is maximum. Thus, the density filter Fj is located at the position of a predetermined defocusing from the aforementioned conjugate plane PL1 in the illumination optical system 1.

For the measurement of the marks 124A, 124B, 124C, and 124D, the blinds 111X1, 111X2, 111Y1, and is 111Y2 and the density filter Fj are arranged as shown in FIG. 10A with respect to the slit 136 of the fixed slit plate 131, the marks 124A and 124B are illuminated by the illumination light IL and measured by a spatial image measurement device, then the blinds 111X1, 111X2, 111Y1, and 111Y2 and the density filter Fj are arranged as shown in FIG. 10B with respect to the slit 136 and the marks 124C and 124D are illuminated by the illumination light IL and similarly measured by the spatial image measurement device. The spatial image measurement device will be explained later.

Further, the number of marks set at the density filter is not limited to four. It is sufficient to set one or more in accordance with the accuracy of setting etc. of the density filter. Further, in this example, in FIG. 2A, pairs of marks were provided at the top side and bottom side of the density filter Fj (upstream side and downstream side of scan direction (Y-axial direction)), hut it is also possible to provide one or more each at each of the sides of the density filter Fj. In this case, the marks may be provided symmetrically about the center of the density filter Fj, but it is preferable to arrange the marks not to become point symmetric about the center of the density filter Fj or to arrange a plurality of marks point symmetrically and form a separate recognition pattern. This is because, when arranging a density filter in an illumination optical system, measuring the energy distribution, then taking out the density filter, correcting it, and resetting it, since the density filter is corrected considering the optical characteristics of the illumination optical system (distortion etc.), the correction would become meaningless if the density filter were reset rotated in position. This arrangement enables the density filter to be reset at the original state.

The density filter Fj may be suitably changed by providing, as shown in FIG. 1, a filter library 16a at the side of the filter stage FS. In this case, the filter library 16a has L number (L is a natural number) of support shelves 17a successively arranged in the Z-direction. Density filters F1, . . . , FL are carried on the support shelves 17a. The filter library 16a is supported to be movable in the Z-direction by a slider 18a. A loader 19a able to freely rotate and provided with an am able to move in a predetermined range in the Z-direction is arranged between the filter stage FS and the filter library 16a. The main control system 9 adjusts the position of the filter library 16a in the Z-direction through the slider 18a, then controls the operation of the loader 19a to enable transfer of desired density filters F1 to FL between the desired support shelves 17a of the filter library 16a and the filter stage FS.

When providing the filter library 16a, the plurality of density filters Fj supported on the support shelves 17a are not particularly limited, but may be selected from among ones set with shapes of the light-blocking part 121, light-transmitting part 122, and light-attenuating part 123 (shape, arrangement, etc.) and light-attenuating characteristics of the light-attenuating part 123 in accordance with the shape of the shots, the arrangement of the shots, the type of the reticle Ri used, etc. For example, it is possible to provide nine density filters F1 to F9 as shown in FIG. 3A to FIG. 3I. These differ from each other in the shapes or positions of the light-attenuating parts 123 and are selectively used in accordance with whether there are portions where the images of patterns overlap between adjoining shot areas at the four sides of the shot areas to be exposed (stitched parts).

That is, in the case of a shot matrix of p (rows)×q (columns), the density filter of FIG. 3A in used for the shot (1,1), the density filter of FIG. 3B is use for the shot (1,2 to q−1), the density filter of FIG. 3C is used for the shot (1,q), the density filter of FIG. 3D is used for the shot (2 to p−1, 1), the density filter of FIG. 3E is used for the shot (2 to p−1, 2 to q−1), the density filter of FIG. 3F is used for the shot (2 to p−1, q), the density filter of FIG. 3G is used for the shot (p,1), the density filter of FIG. 3H is used for the shot (p,2 to q−1), and the density filter 3I is used for the shot (p,q).

Further, the filters Fj may be provided in a one-to-one correspondence with the reticles Ri, but use of the same density filter Fj for exposure of several reticles Ri enables the number of the density filters Fj to be reduced and is more efficient. If the density filters Fj are made able to be used rotated 90 degrees or 180 degrees, by preparing for example the three types of density filters Fj of FIG. 3A, FIG. 3B, and FIG. 3E, it is possible to realize the functions of the other density filters and the efficiency is greater.

In the present embodiment, by using the single density filter Fj shown in FIG. 3E, selecting and setting its relative position with respect to the four blinds 111X1, 111X2, 111Y1, and 111Y2 of the reticle blind mechanism 110, and blocking one or more of the four sides of the light-attenuating part 123 by the corresponding blinds 111X1, 111X2, 111Y1, and 111Y2, it is possible to realize the functions of the density filters shown in FIG. 3A to FIG. 3I and other density filters by a single density filter. It is therefore possible to realize the functions of the various density filters shown in FIG. 3A to FIG. 3I etc. by a single type of density filter Fj and increase efficiency. Further, it is possible to use the density filter Fj shown in FIG. 3E and utilize light-blocking strips of the reticle Ri to block one or more of the four sides of the light-attenuating part 123. For exposure of substrates different in shot size from each other, there may be used a plurality of density filters Fj having the same shape as in FIG. 3E and different in size of the light transmitting part 122 thereof from each other. Further, to change the tilt and width of the slope part at either end of the intensity distribution on the substrate 4 of the illumination light IL in the non-scan direction (X-direction), there may be used a plurality of density filters Fj having the same shape as in FIG. 3E and different in attenuation and width of the light attenuating part 123 from each other.

Further, the density filter Fj is not limited to one comprised of a glass substrate formed with a light-attenuating part or light-blocking part by chrome or another light-blocking material. Use mar also be made of ones using liquid crystal elements etc. to enable the positions of the light-blocking part or light-attenuating part and the light-attenuating characteristics of the light-attenuating part to be changed in accordance with need. In this case, there is no longer a need to prepare several density filters and various demands in the specifications of the working reticles (microdevices) produced can be flexibly dealt with.

As show in FIG. 1 and FIG. 8, the exposure light IL passing through a density filter Fj is shaped by the rectangular slit 136 of the fixed slit plate 131, then travels via a reflection mirror 112 and condenser lens system 113, an imaging lens system 114, a reflection mirror 115, and a main condenser lens system 116 to strike an illuminated area similar to the slit 136 of the fixed slit plate 131 on the circuit pattern area of the reticle Ri. In FIG. 8, for simplification, the reflection mirrors 112 and 115 are not shown. Further, since the exposure apparatus (FIG. 1) according to the present invention is not only applicable for manufacturing a microdevice but also for manufacturing a photomask or reticle (working reticle), the reticle Ri will also be called “master reticle” and the substrate 4 to be exposed also be called “blanks” hereunder.

The exposure light IL emitted from the illumination optical system 1 illuminates part of a master reticle Ri held on the reticle stage 2. The reticle stage 2 holds the i-th (i=1 to N) master reticle Ri.

In the present embodiment, a shelf-like reticle library 16b is arranged at the side of the reticle stage 2. This reticle library 16b has N number (N is a natural number) of support shelves 17b successively arranged in the Z-direction. Master reticles R1, . . . , RN are carried on the support shelves 17b. The reticle library 16b is supported to be movable in the Z-direction by a slider 18b. A loader 19b able to freely rotate and provided with an arm able to move in a predetermined range in the Z-direction is arranged between the reticle stage 2 and the reticle library 16b. The main control system 9 adjusts the position of the reticle library 16b in the Z-direction through the slider 18b, then controls the operation of the loader 19b to enable transfer of desired master reticles F1 to FL between the desired support shelves 17b of the reticle library 16b and the reticle stage 2.

The image of the pattern in the slit-shaped illuminated area of the master reticle Ri is projected on the surface of the substrate for the working reticle (blank) 4 at a reduction rate 1/α (α is for example 5, 4, etc.) through a projection optical system 3. FIG. 4 is a perspective view showing the case of projecting reduced images of parent patterns of a master reticle on to a substrate. In FIG. 4, members the same as the members of the exposure apparatus shown in FIG. 1 are assigned the same reference numerals. In FIG. 1 and FIG. 4, the substrate 4 is a light-transmitting substrate such as silica glass. A thin film of a mask material such as chrome or molybdenum silicide is formed on the pattern area of the surface. Alignment marks 24A and 24B comprised of two two-dimensional marks for positioning use are formed so as to straddle the pattern area 25.

The alignment marks 24A and 24B are formed in advance before transfer of the patterns by using an electron beam lithography system, laser beam lithography system, projection exposure apparatus (stepper, scanner), etc. Further, the surface of the is substrate 4 is coated with a photoresist so as to cover the mask material.

The reticle stage 2 indexes the held master reticle Ri in the XY plane in the rotational direction and the parallel direction to adjust its posture. Further, it enables reciprocating movement in the Y-direction at a fixed speed. The X-coordinate, Y-coordinate, and rotational angle of the reticle stage 2 are measured by not shown laser interferometers. The drive motor (linear motor or voice coil motor etc.) is driven based on the measured values and the control information from the main control system 9 for control of the scan speed and position of the reticle stage 2.

On the other hand, the substrate 4 is prevented from positional deviation due to deformation of the substrate by being placed on a holder comprised of three pins without auction (negative support) or with soft suction. The substrate holder is affixed on the sample table 5. The sample table 5 is affixed on the substrate stage 6. The sample table 5 matches the surface of the substrate 4 with the imaging plane of the substrate 4 by control of the focal position (position in optical axis AX direction) and angle of tilt of the substrate 4 by an auto focus system. There are fixed on the sample table 5 a spatial image measurement sensor 126 and a not shown illumination distribution detection sensor (so-called illumination uniformity sensor), which detect projected images of a fiducial mark member 12, a fiducial mark (not show) to be provided on the reticle stage 2, a mark of the master reticle Ri, and a mark of the density filter Fj. Further, the substrate stage 6 engages in a constant speed scan motion in the Y-direction of the sample table 5 and stepping motion in the X-direction and Y-direction by for example a linear motor.

The X-coordinate, Y-coordinate, and rotational angle of the sample table 5 are measured by movable mirrors 8m affixed above the sample table 5 and laser interferometers 8 arranged facing them. The measured values are supplied to a stage control system 10 and main control system 9. “Movable mirrors 8m” is a generic term for the X-axis movable mirror 8mX and the Y-axis movable mirror 8mY as shown in FIG. 4. The stage control system 10 controls the operation of the linear motor etc. of the substrate stage 6 based on the measured values and the control information from the main control system 9. The rotational error of the substrate 5 is corrected by slightly rotating the reticle stage 2 through the main control system 9.

The main control system 9 sends various types of information such as the position of movement, speed of movement, acceleration of movement, and positional offset of the reticle stage 2 and the substrate stage 6 to the stage control system 10 etc. At the time of scan exposure, the reticle stage 2 and substrate stage 6 are drive synchronously, and synchronously with a movement of the reticle Ri at a velocity Vr in the +Y direction (or in the −Y direction) in relation to the area illuminated with the illumination light IL from the illumination optical system 1, the substrate 4 is moved at a velocity β·Vr (β is ⅕, . . . ) in the −Y direction (or in the +Y direction) in relation to an exposure area (projection area in which a pattern image in the illuminated area is formed) illuminated with the illumination light IL from the projection optical system 3. Thus, in this embodiment, the pattern area 20 of the reticle Ri is entirely exposed to the illumination light IL and one shot area on the substrate 4 is scanned with the illumination light IL to transfer the pattern of the reticle Ri to the shot area.

Further, the main control system 9 has connected to it a storage device 11 such as a magnetic disk drive. The storage device 11 stores an exposure data file. The exposure data file records information relating to the positional relationship among the master reticles R1 to RN, information relating to the density filters for the master reticles R1 to RN, the alignment information, etc.

Next, the measurement device (spatial image measurement device) 126 of the slit marks 124A to 124D (FIG. 2B) comprised of the slit-shaped apertures formed in the density filter Fj will be explained with reference to FIG. 5. In FIG. 5, the substrate stage 6 is provided with a light receiver for measuring the images of the slit marks 124A to 124D, formed on the light-blocking part 121 of the density filter Fj, projected by the projection optical system 3. The light receiver is comprised, as shown in the figure, by a light receiving plate 55 having a rectangular (in this embodiment, square) aperture 54 below which is provided a photoelectric sensor (photoelectric conversion element) 56. The detection signal of the photoelectric sensor 56 is input to the main control system 9. Further, it is also possible to not provide the photoelectric sensor 56 below the aperture 54, but to guide light by a light guide etc. and detect it by a photoelectric sensor etc. at another portion.

Explaining the density filter Fj as shown in FIG. 10A or FIG. 10B, images of the slit marks 124A to 124D projected by the projection optical system 3 are formed on the surface of the light-receiving plate 55. The substrate stage 6 is moved by the main control system 9 to bring the light receiver into register near the position corresponding to one of the projected images of the slit marks 124A to 124D. In that state, as shown in FIG. 11A, by making the aperture 54 of the light receiver scan the projected image 57, a signal shown in FIG. 11B is detected by the photoelectric sensor 56. That is, the lead slit image in the scan direction among projected images of the plurality of slits (light-transmitting parts) of one slit mark appears in the aperture 54, then the adjoining slit images successively appear in the aperture 54. After all of the slit images have appeared in the aperture 54, they are successively moved out of the aperture 54. Finally, all of the slit images are moved out of the aperture 54.

At this time, as shown in FIG. 11B, the output of the photoelectric sensor 56 (amount of light received) increases in substantially equal stages, peaks, then falls in stages along with movement of the projected images 57 of the slits into and out from the aperture 54. Therefore, by detecting the coordinate position of the substrate stage 6 at the peak position of the detected value, it is possible to measure the position of the projected image of the slit mark 125 in the X- or Y-direction.

The above method of measurement measures the position of the projected images of the slit marks 124A to 124D in the X- (or Y-) direction by driving the substrate stage 6 to scan in the X- (or Y-) direction, but by moving in the Z-direction as well (moving the sample table 5 in the vertical direction) at the same time as scanning in the X- (or Y-) direction, it is also possible to detect the imaging position (imaging plane) in addition to the position in the X- (or Y-) direction. That is, if moving not only in the X- (or Y-) direction, but also in the Z-direction, the output of the photoelectric sensor 56 becomes larger in stages in the same way as in FIG. 11B, but the difference in the stages is not equal like in FIG. 11B, but becomes larger the closer the light receiving surface of the sensor 56 to the imaging position and becomes smaller the farther away. Therefore, if differentiating the output signal of the photoelectric sensor 56 for X (or Y) and finding the Z-position where the interpolated curve connecting the plurality of peaks in the differentiated signal becomes the highest$ that position is the imaging position. Therefore, the imaging position can be found extremely easily. By measuring the imaging positions for at least three of the marks 124A to 124D, it in possible to detect not only a shift or rotation of the density filter Fj from a predetermined reference, but also the amount of tilt with respect to the XY plane and it becomes possible to correct the posture for such tilt as well.

Note that the marks 124A to 124D formed on the density filter Fj are not limited to the slit marks 125X and 125Y suited for measurement by this measurement method and may of course also be diffraction grating marks or other marks. Also, the aperture 54 in the light receiving plate 55 has not to be moved simultaneously in the X- or Y-direction and Z-direction but it may be moved repeatedly in the X- or Y-direction and that in the Z-direction to measure an imaging position of each mark. Further, the aperture in the light receiving plate 55 is not limited in shape to the rectangle but it may be formed like a slit for example.

Next, an explanation will be give of the operation of the density filter Fj, blinds 111, reticle Ri, and substrate 4 most characterizing the present embodiment with reference to FIG. 12 to FIG. 16. Note that FIG. 12 to FIG. 16 are substantially the same as FIG. 8 and FIG. 9 except that the driver 137, 138X and 138Y for the density filter Fj and blinds 111 are not illustrated. So, only the operation will be described hereinafter. In FIG. 12A to FIG. 16A, the reticle Ri corresponds to the pattern area 20 and substrate 4 corresponds to one shot area, and also each of the optical system (optical element 113 etc.) provided between the fixed slit plate 131 and reticle Ri and the projection optical system 3 is of an equal magnification type. Further, it should be noted that FIG. 12A to FIG. 16A schematically show the illumination light beam IL, IL1 and IL2 on the fixed slit plate 131, reticle Ri and substrate 4, respectively, as illumination distribution (or light amount distribution) per pulse in the scan direction (Y-direction).

As advance preparations, the posture of the reticle Ri and the posture of the substrate 4 are adjusted to match by alignment processing (details explained later), then the postures of the density filter Fj and the blinds 111 (111X1, 111X2, 111Y1, and 111Y2) are adjusted to match. Further, it is assumed that the substrate 4 is stepped near the shot to be exposed first.

First, as shown in FIG. 12A and FIG. 12B, immediately before the start of exposure, the X-direction blinds 111X1 and 111X2 are set to positions defining the X-direction shot size. Further, the density filter Fj is set to the initial position corresponding to the reticle Ri. At this time, the Y-direction blind 111Y1 (front blind) blocks light IL from the light source 1 from passing through the slit 136 of the fixed slit plate 131 (prevents light from reaching the substrate 4). Further, the Y-direction blinds 111Y1 and 111Y2 are set to positions blocking the outsides of the light-attenuating part 123 of the density filter Fj. The synchronous movement (scan motion) of the density filter Fj blinds 111Y1 and 111Y2, reticle Ri, and substrate 4 is begun from this state. Exposure is started at the point when the speed has sufficiently stabilized.

Immediately after the start of exposures the components become arranged as shown in FIG. 13A and FIG. 13B. The portion of the reticle Ri corresponding to the pattern is illuminated by the slit light IL1 (light passing through the slit 136) adjusted in illumination distribution in accordance with the characteristics of the top side of the light-attenuating part 123 of the density filter FJ and its surroundings, the substrate 4 is illuminated by the illumination light IL2 including the image of the pattern of that portion, and the corresponding pattern is transferred to the substrate 4. AS shown in FIG. 13A and FIG. 13B, one end of the light attenuating part 123 of the density filter Fj is substantially coincident with one end of the slit 136 in the scan direction (Y-direction) and the slit 136 is entirely exposed to the illumination light IL. Therefore, on the reticle Ri and the substrate 4, the illumination light beams IL1 and IL2 show an illumination distribution of which one end is inclined linearly in the scan direction, and a trapezoidal-like illumination distribution of which both ends are inclined linearly in the non-scan direction (X-direction perpendicular to surface of FIG. 13A), respectively.

When the synchronous movement of the density filter Fj, blinds 111Y1 and 111Y2, reticle Ri, and substrate 4 proceeds further, as shown in FIG. 14A and FIG. 14B, the slit 136 reaches the center of the shot. In this state, the illumination distribution of the slit lights ZL1 and ZL2 becomes uniform in the Y-direction, but becomes trapezoidal in the X-direction in accordance with the characteristics of the left side and right side of the light-attenuating part 123 of the density filter Fj.

Immediately before the end of the exposure, as shown in FIG. 15A and FIG. 15B, the portion of the reticle Ri corresponding to the pattern is illuminated by the slit light IL1 adjusted in illumination distribution in accordance with the characteristics of the bottom side of the light-attenuating part 123 of the density filter Fj and its surroundings, the substrate 4 is illuminated by the illumination light IL2 containing the image of the pattern of that portion, and the corresponding image is transferred to the substrate 4. The slit 136 is illuminated just before the illumination light is blocked by the blind 111Y2 and the exposure is completed. That is, as shown in FIG. 15A and FIG. 15B, the other end of the light attenuating part 123 of the density filter Fj is substantially coincident with the other end of the slit 136 in the scan direction and the slit 136 is entirely exposed to the illumination light IL. Therefore, on the reticle Ri and the substrate 4, the illumination light beams IL1 and IL2 show an illumination distribution of which one end is inclined linearly in the scanning direction, and a trapezoidal-like illumination distribution of which both ends are inclined linearly in the non-scan direction (X-direction perpendicular to surface of FIG. 13A), respectively.

Next, as shown in FIG. 16A and FIG. 16B, the slit 136 is completely blocked by the blind 111Y2 and the exposure of the shot ends. Due to this, that shot of the substrate 4 is exposed by a distribution of exposure giving an exposure substantially linearly declining the further the peripheral part of the shot to the outside in accordance with the characteristics of the light-attenuating part 123 of the density filter Fj. Namely, in this embodiment, since the density filter Fj is moved synchronously with the movement of the reticle Ri and the substrate 4, a part of the light attenuating part 123 of the density filter Fj, that is, a pair of light attenuating part extending in the non-scan direction, is kept substantially coincident with the circumference of the shot in consideration on the substrate 4 (in other words, the projected image of the light attenuating part overlaps the circumference of the projected image of the light attenuating part). Therefore, the exposure distribution on the substrate 4 in the scan direction will have the slope part at either end thereof due to the scan exposure of the shot in consideration.

Further, in this embodiment, since the exposure distribution in the non-scan direction slope parts at either end thereof, the exposure can be nearly uniformed on all of a plurality of shots by scanning, with the illumination light on the substrate 4, the shot in consideration and other shots which partially overlap at the circumferences thereof the shot in consideration. Thus, a seamless two-dimensional stitching exposure can be done. Even with a one-dimensional stitching exposure in which a plurality of shots arranged on the substrate 4 along the scan direction are scanned with the illumination light, the amount of exposure can be uniformed on all the shots as in the two-dimensional stitching exposure.

Moreover, when each of a plurality of shots which partially overlap each other at the circumferences thereof on the substrate 4 is scanned with the illumination light, the amount of exposure has to be nearly uniformed at one of the four circumferences of each shot, which does not overlap the other shots, namely, is not doubly exposed. To this end, the reticle blind mechanism 110 for example should be used to shade a part of the light attenuating part 123 of the density filter Fj, which corresponds to the circumference of the shots to be exposed by scanning$ which does not overlap the other shots.

In the operation description having been made in the above with reference to FIG. 12A and FIG. 12B to FIG. 16A and FIG. 16B, it has been described for the simplicity of the illustration and explanation that the density filter Fj is used to cause the illumination distribution on the reticle Ri and substrate 4 to slope at the ends of the latter. However, since the fixed slit plate 131 is off the aforementioned conjugate plane PL1 in the illumination optical system 1, the illumination distribution in the scan direction will show at the end thereof the slope part which also involves the influence of the fixed slit plate 131. Also, in the exposure apparatus shown in FIG. 1, the plurality of reticles is used for stitching exposure as having previously be described. However, the plurality of reticles has not to be used but a single reticle which forms a plurality of patterns may be used instead or a single pattern may be used. Further, in the exposure apparatus shown in FIG. 1, the substrate 4 is supported by the three pins formed in the holder as having previously been described, but a pin chuck holder for example may be used to suck the substrate 4 under vacuum.

The exposure apparatus according to the present invention performs stitch exposure using a plurality of master reticles. This exposure apparatus is used not only when producing a semiconductor integrated circuit, but also when producing a reticle. Here, the explanation will be given of the method of producing the reticle produced using this master reticle Ri and this exposure apparatus, that is, the working reticle 34.

FIG. 6 is a view for explaining the process of production when producing a reticle (working reticle) using a master reticle Ri. The working reticle 34 shown in FIG. 5 is the finally produced reticle. The working reticle 34 is comprised of a light-transmitting substrate made of quartz glass or the like (blank) on one surface of which is formed a master pattern 27 for transfer by chrome (Cr), molybdenum silicide (MoSi₂ etc.), or another mask material. Further, two alignment marks 24A and 24B are formed so as to straddle the master pattern 27.

The working reticle 34 is used in reduction projection of 1/β (where β is an integer larger than 1 or a half integer etc., for example, 4, 5, or 6) through a projection optical system of an optical type projection exposure apparatus. That is, in FIG. 6, a reduced image 27W of 1/β times the master pattern 27 of the working reticle 34 is exposed on each shot area 48 of a wafer W coated with a photoresist, then developed or etched etc. to form predetermined a circuit pattern 35 on each shot area 48.

In FIG. 6, first the circuit pattern 35 of a certain layer of the semiconductor device to be finally produced is designed. The circuit pattern 35 forms various line-and-space patterns (or isolated patterns) in a rectangular area with widths of perpendicular sides of dX and dY. In this embodiment, the circuit pattern 35 is enlarged β times to prepare a master pattern 27 comprised of a rectangular area with widths of perpendicular sides of β·dX and β·dY in the image data of the computer. The multiple β is a reciprocal of the reduction rate (1/β) of the projection exposure apparatus where the working reticle is to be used. Further, the image in inverted and enlarged at the time of inversion projection.

Next, the master pattern 27 is enlarged α-fold (α is an integer larger than 1 or a half integer, for example, 4, 5, or 6) to prepare, in the image data, a parent pattern 36 comprised of a rectangular area with widths of perpendicular sides of α·β·dX and α·β·dY. The parent pattern 36 is then partitioned longitudinally and laterally into α number of sections to prepare α×α number of parent patterns P1, P2, P3 . . . , PN (N=α²) in the image data. In FIG. 6, the case where α=5 is shown. Further, the divisor α of the parent pattern 36 does not necessarily have to match the magnification α of the master pattern 27 to the parent pattern 36. Next, these parent patterns Pi (i=1 to N) are used to produce lithographic data for an electron beam lithography system (or laser beam lithography system) and these parent patterns Pi are transferred on to the master reticle Ri as parent masks at equal magnification rates.

For example, when producing one master reticle R1, a thin film of chrome or molybdenum silicide or other mask material is formed on a light-transmitting substrate of quartz glass etc., an electron beam resist is coated on this, then the electron beam lithography system is used to draw an equal magnification latent image of the first parent pattern P1 on the electron beam resist. Next, the electron beam resist is developed, then is etched and the resist peeled off etc. to for the parent pattern P1 on the pattern area 20 on the master reticle R1.

At this time, alignment marks 21A and 21B comprised of two 2-dimensional marks are formed in a predetermined positional relationship at the parent pattern P1. In the same way, an electron beam lithography system is used to form parent patterns Pi and alignment marks 21A and 21B on other master reticles Ri. These alignment marks 21A and 21B are used for positioning with respect to the substrate or density filter.

In this way, the parent patterns Pi drawn by the electron beam lithography system (or laser beam lithography system) are patterns of the master pattern 27 enlarged α-times, so the amount of the lithographic data is reduced to about 1/α² compared with when directly drawing the master pattern 27. Further, the minimum line width of the parent patterns Pi is α-times (for example 5-times or 4-times) the minimum line width of the master pattern 27, so the parent patterns Pi can be drawn in a short time and at a high accuracy by an electron beam lithography system using conventional electron beam resists. Further, by producing N number of master reticles R1 to RN at one time, it is possible to produce the number of necessary working reticles 34 by repeatedly using them, so the time for producing the master reticles R1 to RN does not become a large burden. The working reticle 34 is produced by using the thus produced N number of master reticles Ri and transferring the 1/α-size reduced images PIi (i=1 to N) of the parent patterns Pi of the master reticles Ri while stitching then together (while partially overlaying them).

Details of the exposure operation of the working reticle 34 using the master reticle Ri will be explained next. First, a first shot area on the substrate 4 is moved to the exposure area (projection area) of the projection optical system 3 by step motion of the substrate stage 6. In parallel with this, a master reticle R1 is loaded and held from the reticle library 16b to the reticle stage 2 through the loader 19b, and a density filter F1 is loaded and held from the filter library 16a to the filter stage FS through the loader 19a. The master reticle R1 and the density filter F1 are aligned etc., then, as explained above, the density filter Fj, blinds 111Y1 and 111Y2, reticle Ri, and substrate 4 are moved synchronously, and a reduced image of the master reticle R1 is sequentially transferred to corresponding shot areas on the substrate 4 through the projection optical system 3.

When the reduced image of the first master reticle R1 finishes being exposed on the first shot area on the substrate 4, the next shot area on the substrate 4 is moved to the exposure start position by step motion of the substrate stage 6. In parallel with this, the master reticle R1 on the reticle stage 2 is unloaded to the library 16 through the loader 19, the next master reticle R2 to be transferred is loaded and held from the library 16 to the reticle stage 2 through the loader 19, the density filter F1 on the filter stage FS is unloaded when necessary to the library 16 through the loader 19, and the next density filter F2 corresponding to the master reticle R2 to be transferred is loaded and held from the library 16 to the filter stage FS through the loader 19. The master reticle R2 and the density filter F2 are aligned etc., then a reduced image of the master reticle R2 is successively transferred to the corresponding shot areas on the substrate 4 through the projection optical system 3.

After this, by the step-and-scan system (step-and-stitch system), reduced images of the corresponding master reticles R3 to RN are successively exposed and transferred on to the remaining shot areas of the substrate 4 while suitably changing the density filters F2 to FN according to need. Note that the density filter has not to he replaced but only the density filter Fj shown in FIG. 2A may be used to scan each shot area on the substrate 4 with the illumination light.

Next, an explanation will be made of the alignment of the substrate 4 an the master reticle at. FIG. 7 shows the reticle alignment mechanism. In FIG. 7, a light-transmitting fiducial mark her 12 is affixed near the substrate 4 on the sample table 5. Two cross-shaped fiducial marks 13A and 13B are for example formed at a predetermined interval in the X-direction on the fiducial mark member 12. At the bottoms of the fiducial marks 13A and 13B is placed an illumination system for illuminating the fiducial marks 13A and 13B at the projection optical system 3 side by illumination light branched from the exposure light IL. When aligning a master reticle Ri, the substrate stage 6 of FIG. 1 is driven to position the fiducial marks 13A and 13B so that the center point between the fiducial marks 131 and 13B on the fiducial mark member 12 substantially registers with the optical axis AX of the projection optical system 3 as shown in FIG. 7.

Further, for example, two cross-shaped alignment marks 21A and 21B are formed so as to straddle the pattern area 20 of the pattern surface (bottom surface) of the master reticle Ri in the X-direction. The distance between the fiducial marks 13A and 13B in set to be substantially equal to the distance between images of the alignment marks 21A and 21B reduced by the projection optical system 3. By illumination by illumination light of the same wavelength as the exposure light IL from the bottom of the fiducial mark member 12 in the state with the center point between the fiducial marks 13A and 13B substantially in register with the optical axis AX in the above way, images of the fiducial marks 13A and 13B enlarged by the projection optical system 3 are formed near the alignment marks 21A and 21B of the master reticle Ri.

Mirrors 22A and 22B are arranged above the alignment marks 21A and 21B to reflect the illumination light from the projection optical system 3 side in the ±X directions. Image processing type alignment sensors 14A and 14B are provided by a TTR (through-the-reticle) system so as to receive the illumination light reflected by the mirrors 22A and 22B. The alignment sensors 14A and 14B are each provided with an imaging system and a 2-dimensional image pickup element such as a CCD camera. The image pickup elements pick up the images of the alignment marks 21A and 21B and the corresponding fiducial marks 13A and 13B and supply image signals to an alignment signal processing system 15 of FIG. 1.

The alignment signal processing system 15 processes the image signals to find the amount of positional deviation of the alignment marks 21A and 21B in the X-direction and Y-direction with respect to the fiducial marks 13A and 13B and supplies the two positional deviations to the main control system 9. The main control system 9 positions the reticle stage 2 so that the two positional deviations become symmetrical and within predetermined ranges. Due to this, the alignment marks 21A and 21B and in turn the parent pattern Pi in the pattern area 20 of the master reticle Ri (see FIG. 6) are positioned with respect to the fiducial marks 13A and 13B.

In other words, the center (exposure center) of the reduced image of the parent pattern Pi of the master reticle Ri obtained by the projection optical system 3 is positioned at the center point between the fiducial marks 13A and 13B (substantially the optical axis AX) and the perpendicular sides of the contour of the parent pattern Pi (contour of pattern area 20) are set to be parallel to the X-axis and Y-axis. In this state, the main control system 9 of FIG. 1 stores the X-direction and Y-direction coordinates (XF₀, YF₀) of the sample table 5 measured by the laser interferometers 8, whereby the alignment operation of the master reticle Ri ends, After this, it is possible to move any point on the staple table 5 to the exposure center of the parent pattern Pi.

Further, as shown in FIG. 1, an image processing type alignment sensor 23 is provided by an off-axis system at the side of the projection optical system 3 to detect the position of a mark on the substrate 4. The alignment sensor 23 illuminates a detection mark by illumination light of a wide band to which the photoresist is not sensitive, picks up the image of the detection mark by a two-dimensional image pickup element such as a CCD camera, and supplies an image signal to the alignment signal processing system 15. Further, the distance (base line amount) between the detection center of the alignment center 23 and the center of the projected image of the pattern of the master reticle Pi (exposure center) is found in advance using a predetermined fiducial mark on the fiducial mark member 12 and stored in the main control system 9.

As shown in FIG. 7, two cross-shaped alignment marks 24A and 24B are formed at the ends of the substrate 4 in the X-direction. After the master reticle Pi is aligned, the substrate stage 6 is driven to successively move the fiducial marks 13A and 13B and the alignment marks 24A and 24B on the substrate 4 to the detection area of the alignment sensor 23 of FIG. 1 and measure the positional deviations of the fiducial marks 13A and 13B and the alignment marks 24A and 24B with respect to the detection center of the alignment sensor 23. The results of the measurements are supplied to the main control system 9. Using these measurement results, the main control system 9 finds the coordinates (XP₀, YP₀) of the sample table 5 when the center point between the fiducial marks 13A and 13B is in register with the detection center of the alignment sensor 23 and the coordinates (XP₁, YP₁) of the sample table 5 when the center point between the alignment marks 24A and 24B is in register with the detection sensor of the alignment sensor 23. This ends the alignment operation of the substrate 4.

As a result, the distances between the center point between the fiducial marks 13A and 13B and the center point between the alignment marks 24A and 24B in the X-direction and the Y-direction become (XP₀-XP₁, YP₀-YP₃). Therefore, by driving the substrate stage 6 of FIG. 1 by exactly the distances (XP₀-XP₁, YP₀-YP₁) with respect to the coordinates (XF₀, YF₀) of the sample table 5 at the time of alignment of the master reticle Ri, it is possible to bring the center point between the alignment marks 24A and 24B of the substrate 4 (center of substrate 4) into register with the center point between the projected images of the alignment marks 21A and 21B of the master reticle Ri (exposure center) with a high accuracy as shown in FIG. 4. From this state, the substrate stage 6 of FIG. 1 may be driven to move the sample table 5 in the X-direction and the Y-direction so as to expose a reduced image PIi of a parent pattern Pi of the master reticle Ri at a desired position with respect to the center of the substrate 4.

That is, FIG. 4 shows the state where a parent pattern Pi of an i-th master reticle Ri is reduced and transferred on to the substrate 4 through the projection optical system 3. In FIG. 4, a rectangular pattern area 25 surrounded by sides parallel to the X-axis and Y-axis is virtually set in the main control system 9 centered on the center point between the alignment marks 24A and 24B of the surface of the substrate 4. The size of the pattern area 25 is the size of the parent pattern 36 of FIG. 6 reduced to 1/α. The pattern area 25 is partitioned equally into α sections in the X-direction and the Y-direction to virtually set shot areas S1, S2, S3, . . . , SN (N=a²). The position of a shot area Si (i=1 to N) is set to the position of a reduced image PIi of the i-th parent pattern Pi when assuming reducing and projecting the parent pattern 36 of FIG. 1 through the projection optical system 3 of FIG. 4.

Further, when exposing one substrate 4, regardless of the change of the master reticle Ri, the substrate 4 is placed, without suction or with soft suction, on the sample table 5 comprised of the three pins, and the substrate stage 6 is made to move by a super-low acceleration and a super-low speed so that the position of the substrate 4 does not shift at the time of exposure. Therefore, since the positional relationship between the fiducial marks 13A and 13B and the substrate 4 does not change during the exposure of one substrate 4, when exchanging the master reticles Ri, it is sufficient to position the master reticle Ri with respect to the fiducial marks 13A and 13B. There is no need to detect the positions of the alignment marks 24A and 24B on the substrate 4 for each master reticle.

Above, an explanation was given of the positioning of the master reticle Ri and the substrate 4, but the master reticle as and the density filter may also be positioned relative to each other based on the results of measurement of the positional information of the marks 124A to 124D. At this time, a slight rotation sometimes occurs in the substrate 4 due to the properties of the substrate stage 6, the yawing error, and other error. Therefore, a slight deviation occurs in the relative postures of the master reticle Ri and the substrate 4. This error is measured in advance or measured during actual processing and the reticle stage 2 or substrate stage 6 controlled so that the postures of the master reticle Ri and the substrate 4 are corrected to become in register so as to cancel this error out. When the posture of the master reticle Ri is changed or adjusted, the posture of the density filter Fj is adjusted to match with it.

After this processing, the main control system 9 projects and exposes the reduced image of the parent pattern Pi on a shot area Si of the substrate 4. In FIG. 4, a reduced image of a parent pattern already exposed in the pattern area 25 of the substrate 4 is shown by a solid line, while an unexposed reduced image is shown by a broken line.

By successively exposing reduced images of parent patterns P1 to PN of the N number of master reticles R1 to RN of FIG. 1 on the corresponding shot areas S1 to SN of the substrate 4 in this way, the reduced images of the parent patterns P1 to PN are exposed while being stitched with the reduced images of the adjoining parent patterns. Due to this, the projected image 26 of the parent pattern 36 of FIG. 1 reduced to 1/α is exposed and transferred on to the substrate 4. Next, the photoresist on the substrate 4 is developed and etched and the remaining resist pattern is peeled off, whereby the projected image 26 on the substrate 4 forms the master pattern 27 as shown in FIG. 6 and the working reticle 34 is completed.

As explained above, according to the exposure apparatus of the present embodiment, since the density filter Fj is made to move in synchronization with the synchronous movement of the reticle Ri and the substrate 4, it is possible to seamlessly stitch shots as desired in the scan direction (Y-direction) and the direction perpendicular to the scan direction (X-direction). Therefore, it becomes possible to seamlessly perform stitch exposure in a two-dimensional direction while enjoying the various advantages of scan exposure.

Here, there are the following advantages of scan exposure. That is, it is possible to use small types of the lenses and other optical components comprising the projection optical system, so it is possible to reduce the distortion, curvature of the imaging plane, tilt of the imaging plane, and other various error. Further, the numerical aperture (NA) can similarly be made high and an improvement in resolution achieved. Further, by leveling the substrate 4 so as to give the optimal focus during the scan operation or deliberately slightly shifting the positional relationship of the reticle Ri and the substrate 4 to adjust the imaging characteristics, it is possible to correct the trapezoidal distortion and possible to correct various types of error.

Further, in the present embodiment, as the slit light IL1 and IL2, use is made of light of a rectangular shape, so even when employing excimer light or other pulse light as the illumination light IL for improving the resolution by shortening the wavelength of the light source, a sufficient averaging effect can be enjoyed. Therefore, unlike the conventional technique of specially shaping the slit light to set the amount of exposure of the stitched parts at a slope, it is possible to reduce the occurrence of uneven exposure.

In an exposure apparatus performing stitch exposure by the scan method such as in the present embodiment, however, since the reticle Ri and the substrate 4 are synchronously moved for the exposure, it is necessary to block the slit light so that it does not expose the substrate 4 before the slit-shaped illumination light reaches the pattern area of the reticle Ri (area formed with pattern to be transferred) and after it passes the pattern area. Therefore, a light-blocking strip (light-blocking area) formed by deposition of chrome etc. is provided at the outside of the pattern area of the reticle Ri. Here, this light-blocking strip has to be made larger than the width of the slit light in the scan direction (dimension between front end of preceding partial illumination light and rear end of following partial illumination light when scanning by a plurality of partial illumination lights apart from each other in the scan direction). In general, consideration is also given to the acceleration and deceleration zones in relation to the maximum acceleration during the scan, so a width sufficiently larger than the width of the slit light must be secured.

A reticle, however, is generally prepared by depositing chrome on a transparent glass substrate. If the deposition area is increased, pinholes and other point defects often occur. If there are point defects in the light-blocking band, a portion which inherently should not be exposed will end up being exposed in a point. In this way, when enlarging the light-blocking strip of a reticle, the problem arises of the probability of occurrence of point defects becoming higher. This is not desirable in plate exposure. Further, if the width of the light-blocking strip is enlarged, the area for inspection of pinholes and other point defects is enlarged and the problem arises of a higher cost of the reticle. The same can be same regarding the light-blocking part 121 of the density filter Fj.

To deal with these problems, in the present embodiment, not only are the blinds 111X1 and 111X2 provided, but also the blinds 111Y1 and 111Y2 moving synchronously with the density filter Fj (reticle Ri and substrate 4) are provided, so there is no problem even if there are point defects (pinholes) etc. in the light-blocking part 121 of the density filter Fj or the light-blocking part formed outside of the pattern area of the reticle Ri.

Since parts of the light-blocking part 123 of the density filter Fj can be selectively blocked by the blinds 111X1, 111X2, 111Y1, and 111Y2, by suitably setting the positions of the blinds in accordance with the positions of the shots to be exposed, it is possible to perform various stitch exposures by a single density filter or a small number of density filters and the efficiency can be improved.

Further, as the drive mechanisms for the substrate stage 6, the reticle stage 2, the filter stage FS, and the blinds 111, for example linear motors can be employed. As the support mechanisms for the stages (moving parts) when using such linear motors, it is possible to use an air flotation system using air bearings or a magnetic flotation system using Lorenz force or reactance force. Further, the stages may be types which move along guides 132X, 132Y, and 133 such as shown in FIG. 9 or may be guideless types not provided with such guides.

A linear motor is comprised of a stator fixed to a base member and a slider fired to the stage moving with respect to the base member. When the stator includes a coil, the slider includes a magnet or other magnet means. When the stator includes a magnet means, the slider includes a coil. Further, a motor with a magnet means included in the slider and a coil included in the stator is called a “moving magnet type linear motor”, while a motor with a coil included in the slider and a magnet means included in the stator is called a “moving coil type linear motor”.

To prevent vibration from occurring in the exposure apparatus due to the reaction force accompanying movement of the stages, for example it is possible to ploy an electrically controlled reaction frame mechanism (active type). This reaction frame mechanism is structured with the stator of the linear motor made to float above the base member by an air bearing or other noncontact means. Further, by connecting a reaction frame provided separately from the exposure apparatus and the stator by a reaction frame provided with an actuator such as a voice coil motor able to be electrically controlled based on control of a controller, controlling the operation of the actuator in accordance with the drive of the stage, and causing a force F to act to cancel out the reaction F acting on the stator, the reaction is made to escape to the floor (ground) through the reaction frame. Further, it is possible to employ a mechanical type reaction frame mechanism (passive type) which simply connects the stator of the linear motor and the reaction frame by a reaction frame (rigid rod).

Further, it is possible to employ a system where an object of substantially the same mass as the moving parts, including the stages is moved by the same acceleration in the opposite direction at the time of movement of the stage so as to cancel out the reaction force. In this case, for example, when the reticle stage 2 and filter stage FS are supported on the same structure and both are driven at the same acceleration and in opposite directions, their respective moving parts may be designed to have the nearly same mass in order to cancel the reaction forces of them against each other.

The portion including the filter stage FS, the blinds 111, and the fixed slit plate 131 is preferably supported an a structure separate from the structure supporting the optical components from the mirror 112 to the lens 116 and the structure supporting the reticle stage 2, the projection optical system 3, and the substrate stage 2. This is so as to reduce the effect due to the reaction force accompanying their movement as much as possible. Note that the components up to the moving part disposed at a position nearest to the reticle (filter stage FS in FIG. 1) in the illumination light system 1 may be provided in any separate structure, and the optical elements disposed at the reticle side may rather be provided in the structure which supports the components such as projection optical system 3 etc.

in the above embodiment, the density filter Fj was made to move in accordance with movement of the reticle lip but for example it is also possible to make at least one optical element in the imaging optical system arranged between the density filter Fj and the reticle Fi (in FIG. 1, 113, 114, etc.) movable, provide a mechanism for adjusting the aberration, imaging magnification, or other optical characteristics of the imaging optical system, and make the distribution of light, that is, a slope part with a gradually decreasing amount of light formed by the light-attenuating part of the density filter Fj, in the area of the substrate 4 illuminated by the illumination light IL (the aforementioned exposure area) move relatively in the scan direction (Y-direction) by adjusting the optical characteristics during the scan exposure. That is, during scan exposure of one shot on the substrate 4, the slope part of the light amount distribution (illumination distribution) in the aforementioned exposure area should be shifted nearly along at least one of a pair of circumferences extending along the non-scan direction (X-direction) in which the exposure distribution has to slope. Further, the density filter Fj was arranged in the illumination optical system, but for example it may also he arranged near the reticle Ri or arranged at the imaging plane side of the projection optical system 3. Further, when using an optical system which forms an intermediate image of the reticle pattern and reimages the intermediate image on the substrate 4 as the projection optical system 3, the density filter Fj may be arranged on the plane of formation of the intermediate image or exactly a predetermined distance away from the plane of formation.

Note that in case the density filter Fj is disposed in a plane (PL1 or the like) conjugate with the surface of the substrate 4 (image plane of the projection optical system 3) in the illumination optical system (or projection optical system), a diffusion plate should preferably be provided between the density filter Fj and substrate 4 for example, or at least one optical element disposed between the density filter Fj and reticle Ri should preferably be moved, to make indefinite the dot pattern image on the substrate 4, namely, to prevent the illumination uniformity from being degraded by the dot pattern. In this case, the density filter Fj may be disposed off the conjugate plane or the dot size of the density filter Fj has not to be smaller than the limit of resolution of the optical system (optical element 113 etc.) provided between the density filter Fj and reticle Ri. In this embodiment, the light attenuating part 123 of the density filter Fj is formed on one and same transparent substrate. However, the light attenuating part 123 may be formed from two or more attenuating part which are formed on different transparent substrates, respectively. For example, the light attenuating part 123 may be formed from a pair of light attenuating part extending in the scan direction and a pair of light attenuating parts extending in the non-scan direction.

Also in this embodiment, the fixed slit plate 131 is disposed in the illumination optical system. However, it may be disposed near to the reticle Ri or the substrate 4 for example, or near to a middle image in the projection optical system 3. Further, the fixed slit plate 131 may be disposed in a plane conjugate with the surface of the substrate 4 in the illumination optical system (or the projection optical system). in this case, for example the aberration etc. of the optical system disposed between the fixed slit plate 131 and reticle Ri should be adjusted to allow the intensity distribution of the illumination light IL on the substrate 4 in the scan direction (Y-direction) to slope at either end thereof. Note that although the fixed slit plate 131 is provided separately from the reticle blind mechanism 110 in the aforementioned embodiment, the fixed slit plate 131 may be omitted by modifying the embodiment such that the blinds 111Y1 and 111Y2 are controlled to move independently during scan exposure to define the width of the illumination light IL on the reticle Ri and the substrate 4 in the scan direction.

Further in the aforementioned embodiment, the blinds 111Y1 and 111Y2 of the reticle blind mechanism 110 and the density filter Fj are driven independently. However, at least a part of the reticle blind mechanism 110, for example, the blinds 111Y1 and 111Y2 may be provided on the filter stage FS for movement along with the density filter Fj. In this case, the drive mechanism 138Y for the blinds 111Y1 and 111Y2 may be omitted, but there may be provided a fine-movement mechanism which adjusts the positional relation between the blinds provided on the filter stage FS and density filter Fj. Also, the reticle blinding mechanism 110 may have at least one of the blinds disposed near to the reticle Ri or substrate 4 or in a plane conjugate with the surface of the substrate 4 (plane in which the aforementioned middle image is formed, or the like). in this case, for example the blinds 111X1 and 111X2 and blinds 111Y1 and 111Y2 may be disposed nearly conjugate with each other with respect to a relay optical system or the like. Further, instead of the blinds 111Y1 and 111Y2 of the reticle blind mechanism 110, it suffices only to increase the width of the light blocking part 121 (in FIG. 2A) on the density filter Fj in the scan direction (Y-direction). In this case, the width of the light blocking part 121 should desirably be equal to larger than the aperture width of the slit 136 in the fixed slit plate 131 in the scan direction for example. Since normally the magnification of the optical system disposed between the density filter Fj and reticle Ri is larger than “1”, the width of the light blocking part 121 on the density filter Fj may be small as compared with an increased width of the light blocking area on the reticle Ri, and the light blocking part 121 can easily be formed without causing a defect such as pinhole or the like. Note that when the blinds 111Y1 and 111Y2 are omitted, the fixed slit plate 131 has to be provided to define the width of the aforementioned exposure area (illuminated area) in the scan direction.

In the aforementioned embodiment, the optical integrator 106 uses a fly-eye lens having the light-incident surface thereof disposed substantially in a plane conjugate with the surface of the reticle Ri in which a pattern is formed in the illumination optical system, and the light outgoing surface thereof disposed substantially in a Fourier transform plane (pupil plane of the illumination optical system) to the pattern-formed surface. However, the optical integrator 106 may use an internal-reflection type integrator having the light outgoing surface thereof disposed substantially in a plane conjugate with the pattern-formed surface of the reticle at in the illumination optical system. In this case, at least one of at least a part of the aforementioned reticle blind mechanism 110, density filter Fj and fixed slit plate 131 may be provided in the vicinity of the light outgoing surface of the internal-reflection type integrator.

Note that, in the above embodiment, the shot area was made a rectangular shape, but it does not necessarily have to be a rectangular shape. It may also be a pentagon, hexagon, or other polygon in shape. Further, the shot areas do not have to be the same shapes and say be made different shapes or sizes. Further, the portions to be stitched do not have to he rectangular and may be zigzag strips, serpentine strips, and other shapes as well. In this case, the density filter (overall shape, shape of light-attenuating part, light-attenuation characteristics, etc.) is also changed accordingly. Further, the “stitching” in the specification of the present application is used in the sense including not only stitching of patterns, but also arrangement of patterns in a desired positional relationship.

It is also possible to enlarge the device pattern to be formed on the working reticle 34, partition the enlarged device pattern into element patterns, divide these into for example dense patterns and isolated patterns, and then form them on the master reticles to thereby eliminate or reduce the stitching portions of parent patterns on the substrate 4. In this case, depending on the device pattern of the working reticle, sometimes the parent pattern of one master reticle is transferred to a plurality of areas on a substrate 4 so the number of master reticles used for production of the working reticle can he reduced. Further, it is also possible to partition the enlarged pattern into functional block units of for example a CPU, DRAM, SRAM, A/D converter, and D/A converter and form one or more functional blocks at a plurality of master reticles.

Further, when dense patterns and isolated patterns are formed for example in the master pattern 27 of FIG. 6, sometimes only dense patterns are formed in one master reticle Ra of the master reticles R1 to RN and only isolated patterns are formed in another one master reticle Rb. At this time, since the optimal illumination conditions or imaging conditions or other exposure conditions differ between dense patterns and isolated patterns, it is also possible to optimize the exposure conditions, that is, the shape and size of the aperture stop in the illumination optical system 1, the coherence factor (σ-value), and the numerical aperture of the projection optical system 3, in accordance with the parent pattern Pi for each exposure of a master reticle Ri.

At this time, when the parent pattern is a dense pattern (periodic pattern), it is possible to employ the modified illumination method and define the shape of the secondary light source as a annular shape or a plurality of local areas at substantially equal intervals away from the optical axis of the illumination optical system. Further, to optimize the exposure conditions, it is possible to insert an optical filter (so-called pupil filter) for blocking the illumination light by a circular area centered on the optical axis near the pupil plane of the projection optical system 3 or make dual use of the so-called progressive focusing method (flex method) of causing relative vibration between the imaging plane of the projection optical system 3 and the surface of the substrate 4 within a predetermined range.

Further, it is possible to make the parent mask a phase shift mask, make the α-value of the illumination optical system 0.1 to 0.4 or so, and employ the above progressive focusing method. The photomask is not limited to a mask comprised of a chrome or other light-blocking layer and may also be a spatial frequency modulation type (Shibuya-Levenson type), edge enhancement type, halftone type, or other phase shift mask. In particular, with a spatial frequency modulation type or edge enhancement type, a phase shifter parent mask is separately prepared for patterning a phase shifter to be overlaid on the light-blocking pattern on the mask substrate.

In the above embodiment, the illumination light for exposure was made ArF excimer laser light of a wavelength of 193 nm, but it is also possible to use higher or lower ultraviolet light, for example, g-rays or i-rays or KrF excimer laser or other distant ultraviolet (DUV) light, or F₂ laser (wavelength 157 nm) or Ar, laser (wavelength 126 nm) or other vacuum ultraviolet (VUV) light.

Further, in an exposure apparatus using an F₂ laser, the reticle or density filter used is one made of fluorite, fluorine-doped silica glass, magnesium fluoride, LiF, LaF₃, and lithium-calcium-aluminum fluoride (LiCaAlF crystal), or rock crystal.

Further, instead of an excimer laser, it is also possible to use a harmonic of a YAG laser or other solid laser having an oscillation spectrum at any of a wavelength of 248 nm, 193 nm, and 157 nm.

Further, it is possible to use an infrared region or visible region single wavelength laser light emitted from a DFB semiconductor laser or fiber laser amplified by for example an erbium (or both erbium and yttrium) doped fiber amplifier and use the harmonic obtained by converting the wavelength to ultraviolet light using a nonlinear optical crystal.

Further, it is also possible to use light of a soft X-ray region emitted from a laser plasma light source or SOR, for example, EUV (extreme ultraviolet) light of a wavelength of 13.4 nm or 11.5 nm.

The projection optical system is not limited to a reduction system and may also be an equal magnification system or an enlargement system (for example, used by an exposure apparatus for producing a liquid crystal display or plasma display or the like). Further, the projection optical system may be any of a reflection system, a refraction system, and a catiodioptic system.

Further, the present invention way also he applied to apparatuses other than an exposure apparatus used for the production of a photomask or semiconductor device, such as an exposure apparatus transferring a device pattern on a glass plate used for the production of a display including liquid crystal display elements, an exposure apparatus transferring a device pattern on a ceramic wafer used for production of a thin film magnetic head, an exposure apparatus used for production of a pickup element (CCD), micromachine, DNA chip, etc., and the like.

In an exposure apparatus used for other than production of a photomask (working reticle), the exposure substrate (device substrate) to which the device pattern is to be transferred is held on the substrate stage 6 by vacuum or electrostatics. In an exposure apparatus using EUV rays, however, a reflection type mask is used, while in a proximity type X ray exposure apparatus or electron beau exposure apparatus etc., a transmission type mask (stencil mask, membrane mask) is used, so a silicon wafer etc. is used as the master of the mask.

The exposure apparatus of the present embodiment may be produced by assembling an illumination optical system comprised of a plurality of lenses and a projection optical system into the body of the exposure apparatus and optically adjusting them, attaching the reticle stage or substrate stage comprised of the large number of mechanical parts to the exposure apparatus body and connecting the wiring and piping, and further performing overall adjustment (electrical adjustment, confirmation of operation, etc.) Note that the exposure apparatus is desirably manufactured in a clean room controlled in temperature and cleanness etc.

The semiconductor device is produced through a step of design of the functions and performance of the device, a step of production of a working reticle by the exposure apparatus of the above embodiment based on the design step, a step of production of a wafer from a silicon material, a step of transferring a pattern of the reticle on to a wafer using an exposure apparatus of the present embodiment a step of assembly of the device (including dicing, bonding, packaging, etc.), and an inspection step.

The present invention is of course not limited to the above embodiments and may be modified in various ways within the scope of the invention.

According to the present invention, there is the effect that it is possible to provide an exposure method and an exposure apparatus able to realize seamless stitch exposure not only in a direction perpendicular to the scan direction, but also a direction along the scan direction. Further, even when using pulse light as the illumination light, there is the effect that the uniformity of the line width or pitch of the patterns at the stitched parts is good and patterns can be formed with a high accuracy.

The present disclosure relates to subject matter contained in Japanese Patent Application No. 2000-109144, filed an Apr. 11, 2000, and Japanese Patent Application No. 3001-071572, filed on Mar. 14, 2001, the disclosure of which is expressly incorporated herein by reference in its entirety.

1. An exposure method which irradiates a slit-shaped energy beam on a mask and a sensitive object while moving them synchronously so as to sequentially transfer images of patterns formed on the mask to the sensitive object, including
a step of moving a density filter having a attenuating part for gradually reducing an amount of energy of the energy beam in sychronization with the movement of the mask.

2. An exposure method as set forth in claim 1, wherein a light-blocking member able to advance into and retract from said energy beam is moved in synchronization with movement of said density filter.

3. An exposure method as set forth in claim 2, wherein said light-blocking member is moved in a state positioned to block part of the density filter.

4. An exposure method as set forth in claim 1, wherein part of said attenuating part is selectively blocked by a light-blocking member able to advance into and retract from said energy beam.

5. An exposure method as set forth in claim 1, wherein different areas on said sensitive object are irradiated by said energy beam for seamless exposure such that parts irradiated by said energy beam on said sensitive object through said attenuating part overlap as stitched parts.

6. An exposure method as set forth in claim 5, wherein different areas on said sensitive object in a direction along a direction of movement of said sensitive object are irradiated by said energy beam.

7. An exposure method as set forth in claim 6, wherein different areas on said sensitive object in a direction perpendicular to said direction of movement are irradiated by said energy beam.

8. An exposure method as set forth in claim 5, wherein a pattern obtained by enlarging a pattern for transfer is partitioned into patterns of a plurality of masks and images of said masks reduced by a projection optical system are successively transferred to a plurality of areas on said sensitive object with partially overlapping peripheral parts.

9. An exposure method which relatively moves a mask and a sensitive object with respect to an energy beam and scans and exposes the sensitive object by the energy beam through the mask, including
a step of gradually reducing an amount of energy in a part of an area irradiated by the energy beam on the sensitive object in a first direction in which the sensitive object is moved, while relatively moving a slope part where the amount of energy is gradually reduced in the first direction in said irradiated area during the scan exposure.

10. An exposure method as set forth in claim 9, wherein the slope part is moved in a state of corresponding substantially with a part to which an amount of exposure energy in the first direction of a predetermined area by which scan exposure is carried out on the sensitive object reduces.

11. An exposure method as set forth in claim 9, wherein the slope part is moved in a state of corresponding substantially with a part of a predetermined area, which partially overlaps an area adjacent to the predetermined area in the first direction.

12. An exposure method as set forth in claim 9, wherein a density filter having an attenuating part for forming the slope part is made to relatively move with respect to said energy beam in accordance with movement of said mask.

13. An exposure method as set forth in claim 12, wherein a relative positional relationship between a blocking member for blocking said energy beam and said density filter is adjusted before the scan exposure.

14. An exposure method as set forth in claim 9, wherein the slope part is moved relatively in the first direction in the irradiated area when scanning and exposing at least two areas arranged in the first direction out of a plurality of areas for transferring patterns to the plurality of areas on the sensitive object with partially overlapping peripheral parts by a step-and-stitch system.

15. An exposure method as set forth in claim 14, wherein the amount of energy in the irradiated area is made to be gradually reduced relative to a second direction perpendicular to the first direction in order to scan and expose at least two areas aligned in the second direction out of said plurality of areas.

16. A photomask produced using the exposure method of claim 1 or claim 9.

17. A method of manufacture of a device including a step of transferring a pattern for transfer to a device substrate using a photomask of claim 16.

18. An exposure apparatus which irradiates a slit-shaped energy beam on a mask and a sensitive object while moving them synchronously so as to sequentially transfer images of patterns formed on the mask to the sensitive object, comprising
a density filter which adjusts the distribution of energy of the energy beam and
a filter stage which moves the density filter in synchronization with the mask.

19. An exposure apparatus comprising:
a mask stage which moves a mask,
a substrate stage which moves a substrate,
an illumination optical system which irradiates a slit-shaped energy beam,
a filter stage which moves a density filter having an attenuating part for gradually reducing an amount of energy of said energy beam and
a controller which controls said mask stage, said substrate stage, and said filter stage so that said substrate and said density filter move synchronously with respect to said energy beam.

20. An exposure apparatus as set forth in claim 19, further comprising
a blind mechanism having a light-blocking member able to advance and retract in a direction along the direction of movement of the mask,
said controller controlling the blind mechanism so that said light-blocking member moves synchronously with said density filter in a state maintaining a predetermined positional relationship with said density filter.

21. An exposure apparatus which relatively moves a mask and a sensitive object with respect to an energy bean and scans and exposes the sensitive object by the energy beam through the mask, comprising:
a density filter which gradually reduces an amount of energy in a part of an area irradiated by the energy beam on the sensitive object in a first direction in which the sensitive object is moved and
an adjuster which shifts a slope part where the amount of energy is gradually reduced in the first direction in said irradiated area during the scan exposure.

22. An exposure apparatus as set forth in claim 21, wherein said adjuster includes a drive mechanism which moves said density filter relative to said energy beam in accordance with movement of said mask.

23. An exposure apparatus as set forth in claim 21, wherein at least two areas on said sensitive object with partially overlapped peripheral parts and aligned in said first direction are scanned and exposed for transferring patterns on said at least two areas by the step-and-stitch system.

24. An exposure apparatus as set forth in claim 23, wherein said density filter gradually reduces the amount of energy in said irradiated area at an end in said second direction so as to scan and expose at least two areas which partially overlap at their peripheral parts on the sensitive object and are aligned in a second direction perpendicular to said first direction.

25. An exposure apparatus in which a mask and a sensitive object are moved relative to an energy beam and the sensitive object is scanned exposed by the energy beam through the mask, comprising:
a first optical unit which defines the width of an area irradiated by the energy beam on the sensitive object in a first direction in which the sensitive object is moved during the scan exposure; and
a second optical unit which gradually reduces an amount of energy in a part of the irradiated area in the first direction, while shifting a slope part which the amount of energy is gradually reduced in the first direction within the irradiated area during the scan exposure.

26. An exposure apparatus as set forth in claim 25, wherein the second optical unit shifts the slope part in a state of corresponding substantially with a part which an amount of exposure energy in the first direction of a predetermined area by which scan exposure is carried out on the sensitive object reduces.

27. An exposure apparatus as set forth in claim 25, wherein the second optical unit shifts the slope part in a state of corresponding substantially with a part of a predetermined area, which partially overlaps an area adjacent to the predetermined area in the first direction.

28. An exposure apparatus as set forth in claim 25, wherein the second optical unit includes a density filter having an attenuating part for forming the slope part and the density filter is shifted synchronously with movement of the mask and the sensitive object.

29. An exposure apparatus as set forth in claim 28, wherein the first optical unit includes a stop member having an opening width thereof fixed in the first direction and the density filter has a light shielding part formed adjacent to the attenuating part in the first direction and whose width is equal to or larger than the opening width of the stop member.

30. An exposure apparatus as met forth in claim 28, wherein the first optical unit includes a movable stop member which prevents an area outside the slope from being irradiated with the energy beam in the first direction in the irradiated area and at least a part of the movable stop member is moved in accordance with movement of the density filter.

31. An exposure apparatus as set forth in claim 30, wherein the first optical unit includes a stop member different from the movable stop member and having a fixed opening width in the first direction.

32. An exposure apparatus as set forth in claim 28, wherein the density filter gradually decreases the amount of energy at the end of the irradiated area in a second direction perpendicular to the first direction.

33. An exposure apparatus as set forth in claim 25, wherein the first optical unit gradually reduces the amount of energy at the end of the irradiated area in the first direction.

34. A method of manufacture of a photomask including a step of transferring a plurality of patterns an a mask substrate by a step-and-stitch method using an exposure apparatus of claim 18, 19, or 21.

35. A method of manufacture of a photomask as set forth in claim 34, where said plurality of patterns are obtained by partitioning an enlarged pattern of a device pattern to be formed on the photomask into a plurality of patterns and wherein images of them reduced by a projection optical system are transferred on a plurality of areas partially overlapping at their peripheral parts on the mask substrate.
